(19) United States
(12) Patent Application Publication
(10) Pub. No.: US 2015/0194441 A1
(43) Pub. Date: Jul. 9, 2015

(54) METHOD FOR MANUFACTURING SEMICONDUCTOR DEVICE

(71) Applicant: TOKYO ELECTRON LIMITED, Tokyo (JP)

(72) Inventors: Koichi YATSUDA, Tokyo (JP); Takaaki TSUNOMURA, Tokyo (JP); Takashi HAYAKAWA, Tokyo (JP); Hiromasa MOCHIKI, Tokyo (JP); Kazuhide HASEBE, Yamanashi (JP)

(73) Assignee: TOKYO ELECTRON LIMITED, Tokyo (JP)

(21) Appl. No.: 14/592,281

(22) Filed: Jan. 8, 2015

(30) Foreign Application Priority Data
Jan. 9, 2014 (JP) 2014-002598

(51) Int. Cl. H01L 27/115; H01L 21/28

(52) U.S. Cl. CPC H01L 27/11582; H01L 27/11573; H01L 21/28282

(57) ABSTRACT

Disclosed is method of manufacturing a semiconductor device. The method includes: forming an insulating film on one side of a substrate; forming a carbon film on the insulating film formed in the forming of the insulating film; forming an insulating film-carbon film laminate including a plurality of insulating films and carbon films alternately laminated on the one side of the substrate, by repeating the forming of the insulating film and the forming of the carbon film multiple times; removing the carbon films included in the insulating film-carbon film laminate; and forming electrode films in regions from which the carbon films are removed in the removing of the carbon films to obtain an insulating film-electrode film laminate in which the insulating films and the electrode films are laminated in a plurality of layers.

### CROSS-REFERENCE TO RELATED APPLICATIONS

This application is based on and claims priority from Japanese Patent Application No. 2014-002598, filed on Jan. 9, 2014, with the Japan Patent Office, the disclosure of which is incorporated herein in its entirety by reference.

### TECHNICAL FIELD

The present disclosure relates to a method of manufacturing a semiconductor device.

### BACKGROUND

In the semiconductor device field, a laminated semiconductor device has recently been attracting attention to so as to achieve a high integration without being constrained to the limits of a lithography technology.

For example, Japanese Laid-Open Patent Publication No. 2009-117843 discloses a method of manufacturing a vertical semiconductor device in which interlayer insulating films and sacrificial films are alternately formed in a plurality of layers on a substrate, the sacrificial films are removed by a wet etching process, and a tunnel oxide film, a charge trap film, or a conductive material is disposed in a portion from which the sacrificial films are removed.

### SUMMARY

The present disclosure provides a method of manufacturing a semiconductor device. The method includes: forming an insulating film on one side of a substrate; forming a carbon film on the insulating film formed in the forming of the insulating film; forming an insulating film-carbon film laminate including a plurality of insulating films and carbon films alternately laminated on the one side of the substrate by repeating the forming of the insulating film and the forming of the carbon film multiple times, removing the carbon films included in the insulating film-carbon film laminate; and forming electrode films in regions from which the carbon films are removed in the removing of the carbon films to obtain an insulating film-electrode film laminate in which the insulating films and the electrode films are laminated in a plurality of layers.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is an explanatory view illustrating an insulating film-carbon film laminate in a first exemplary embodiment according to the present disclosure.

FIG. 2 is a view illustrating a part of FIG. 1 in an enlarged scale in a case where silicon film are formed.

FIG. 3A is an explanatory view illustrating a trench forming process in the first exemplary embodiment according to the present disclosure.

FIG. 3B is an explanatory view illustrating the trench forming process in the first exemplary embodiment according to the present disclosure.

FIG. 4A is an explanatory view illustrating a memory string forming process in the first exemplary embodiment according to the present disclosure.

FIG. 4B is an explanatory view illustrating the memory string forming process in the first exemplary embodiment according to the present disclosure.

FIG. 4C is an explanatory view illustrating the memory string forming process in the first exemplary embodiment according to the present disclosure.

FIG. 5A is an explanatory view illustrating an electrode forming process in the first exemplary embodiment according to the present disclosure.

FIG. 5B is an explanatory view illustrating the electrode forming process in the first exemplary embodiment according to the present disclosure.

FIG. 5C is an explanatory view illustrating the electrode forming process in the first exemplary embodiment according to the present disclosure.

FIG. 5D is an explanatory view illustrating the electrode forming process in the first exemplary embodiment according to the present disclosure.

FIG. 6 is an explanatory view illustrating a configuration of a semiconductor device after insulating films are formed between memory strings in the first exemplary embodiment according to the present disclosure.

FIG. 7A is an explanatory view illustrating a word line contact forming process in the first exemplary embodiment according to the present disclosure.

FIG. 7B is an explanatory view illustrating the word line contact forming process in the first exemplary embodiment according to the present disclosure.

FIG. 7C is an explanatory view illustrating the word line contact forming process in the first exemplary embodiment according to the present disclosure.

FIG. 8 is an explanatory view illustrating a configuration of the semiconductor device after an insulating film is formed on a word line contact in the first exemplary embodiment according to the present disclosure.

FIG. 9A is an explanatory view illustrating a word line contact forming process in a second exemplary embodiment according to the present disclosure.

FIG. 9B is an explanatory view illustrating the word line contact forming process in the second exemplary embodiment according to the present disclosure.

FIG. 9C is an explanatory view illustrating the word line contact forming process in the second exemplary embodiment according to the present disclosure.

FIG. 9D is an explanatory view illustrating the word line contact forming process in the second exemplary embodiment according to the present disclosure.

FIG. 10 is an explanatory view illustrating a configuration of a semiconductor device after an insulating film is formed on a word line contact in the second exemplary embodiment according to the present disclosure.

FIG. 11A is an explanatory view illustrating an electrode forming process and a process of forming insulating films between memory strings in the second exemplary embodiment according to the present disclosure.

FIG. 11B is an explanatory view of the electrode forming process and the process of forming insulating films between memory strings in the second exemplary embodiment according to the present disclosure.

FIG. 12 is an explanatory view illustrating an electrode film-carbon film laminate in a third exemplary embodiment according to the present disclosure.

FIG. 13 is an explanatory view illustrating a configuration of a semiconductor device after memory strings are formed in the third exemplary embodiment according to the present disclosure.

FIG. 14 is an explanatory view illustrating the configuration of the semiconductor device after insulating films are formed between memory strings in the third exemplary embodiment according to the present disclosure.

FIG. 15A is an explanatory view illustrating a word line contact forming process in the third exemplary embodiment according to the present disclosure.

FIG. 15B is an explanatory view illustrating the word line contact forming process in the third exemplary embodiment according to the present disclosure.

FIG. 15C is an explanatory view illustrating the word line contact forming process in the third exemplary embodiment according to the present disclosure.

FIG. 16A is an explanatory view illustrating a carbon film removing process in the third exemplary embodiment according to the present disclosure.

FIG. 16B is an explanatory view illustrating the carbon film removing process in the third exemplary embodiment according to the present disclosure.

FIG. 17A is an explanatory view illustrating an insulating film forming process in the third exemplary embodiment according to the present disclosure.

FIG. 17B is an explanatory view illustrating the insulating film forming process in the third exemplary embodiment according to the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

In the method of manufacturing the vertical semiconductor device, disclosed in Japanese Laid-Open Patent Publication No. 2009-117843, all the sacrificial films need to be removed by the wet etching, and the interlayer insulating films may be deflected due to a surface tension of an etching liquid when the wet etching is performed. When the interlayer insulating films are deflected, an interlayer distance may not be constantly maintained. Thus, in the subsequent process, for example, the conductive material may not be uniformly supplied into the gaps between layers, so that a problem such as, for example, a reduction of the yield may be caused.

The present disclosure has been made in view of the problems in the conventional technology described above, and an object of the present disclosure is to provide a method of manufacturing a semiconductor device using a sacrificial film, in which a laminated structure of the sacrificial film and a film formed of another material is formed, and then the sacrificial film is capable of being removed by a dry removal means.

In view of the problems, an aspect of the present disclosure provides a method of manufacturing a semiconductor device. The method includes: forming an insulating film on one side of a substrate; forming a carbon film on the insulating film formed in the forming of the insulating film; forming an insulating film-carbon film laminate including a plurality of insulating films and carbon films alternately laminated on the one side of the substrate, by repeating the forming of the insulating film and the forming of the carbon film multiple times; removing the carbon films included in the insulating film-carbon film laminate; and forming electrode films in regions from which the carbon films are removed in the removing of the carbon films to obtain an insulating film-electrode film laminate in which the insulating films and the electrode films are laminated in a plurality of layers.

In the semiconductor device manufacturing method, the removing of the carbon films is performed by an ashing processing using oxygen plasma.

In the semiconductor device manufacturing method, the electrode films formed in the forming of the electrode films are tungsten-containing films.

The semiconductor device manufacturing method may further include forming a silicon film before and after the forming of the carbon film is performed.

In the semiconductor device manufacturing method, the silicon film is oxidized in the removing of the carbon films.

In the semiconductor device manufacturing method, in the forming of the carbon film, a film formation temperature of the carbon film is set to range from 500° C. to 900° C.

In the semiconductor device manufacturing method, the insulating film formed in the forming of the insulating film is a silicon oxide film.

The semiconductor device manufacturing method may further include: forming a plurality of hard mask films on the insulating film-carbon film laminate; and etching the insulating films and the carbon films using the hard mask films as a mask. The hard mask films include a first inorganic material layer, and a second inorganic material layer made of a material different from a material for the first inorganic material layer.

The semiconductor device manufacturing method may further include: forming a word line contact by processing the insulating films and the carbon films in a stepwise form at an end portion of the insulating film-carbon film laminate. The forming of the word line contact includes: disposing a mask on the insulating film-carbon film laminate; etching the insulating film to remove a part of the insulating film; performing a trimming process to remove a part of the mask and a part of the carbon film; and repeating alternately the etching of the insulating film and the trimming process.

The semiconductor device manufacturing method may further include: forming a trench to penetrate the insulating films and the carbon films of the insulating film-carbon film laminate, and filling the trench with silicon nitride.

Another aspect of the present disclosure provides a method of manufacturing a semiconductor device. The method includes: forming an electrode film on one side of a substrate; forming a carbon film on the electrode film formed in the forming of the electrode film; forming an electrode film-carbon film laminate including a plurality of electrode films and carbon films alternately laminated on the one side of the substrate, by repeating the forming of the electrode film and the forming of the carbon film multiple times; and removing the carbon films included in the electrode film-carbon film laminate.

In the semiconductor device manufacturing method, the removing of the carbon films is performed by an ashing processing using oxygen plasma.

The semiconductor device manufacturing method further includes forming an insulating film in a region from which the carbon films are removed in the removing of the carbon films.

In the semiconductor device manufacturing method, the insulating film is a silicon oxide film.

In the semiconductor device manufacturing method, a region between the electrode films from which the carbon films are removed in the removing of the carbon films forms an air gap.

In the semiconductor device manufacturing method, in the forming of the carbon film, a film formation temperature of the carbon film is set to range from 500° C. to 900° C.

In the semiconductor device manufacturing method, the electrode films formed in the forming of the electrode films are tungsten-containing films.

The semiconductor device manufacturing method further includes forming a plurality of hard mask films on the electrode film-carbon film laminate; and etching the electrode films and the carbon films using the hard mask films as a mask. The hard mask films include a first inorganic material layer and a second inorganic material layer made of a material different from a material for the first inorganic material layer.

According to the present disclosure, there is provided a method of manufacturing a semiconductor device using a sacrificial film, in which a laminated structure of the sacrificial film and a film formed of another material is formed, and the sacrificial film is capable of being removed by a dry removal means.

Hereinafter, exemplary embodiments of the present disclosure will be described with reference to drawings, but the present disclosure is not limited to the exemplary embodiments. Various modifications and substitutions may be made in the exemplary embodiments without departing from the scope of the present disclosure.

### First Exemplary Embodiment

In the present exemplary embodiment, an exemplary configuration of a method of manufacturing a semiconductor device will be described. In the present exemplary embodiment, a NAND-type flash memory is manufactured as the semiconductor device. However, the present disclosure is not limited to the exemplary embodiment but may be generally applied to laminated semiconductor devices.

The method of manufacturing the semiconductor device of the present exemplary embodiment may include the following processes.

An insulating film forming process in which an insulating film is formed on one side of a substrate.

A carbon film forming process in which a carbon film is formed on the insulating film formed in the insulating film forming process.

An insulating film-carbon film laminate forming process in which the insulating film forming process and the carbon film forming process are repeated multiple times to form an insulating film-carbon film laminate including insulating films and carbon films which are alternately laminated in a plurality of layers on the one side of the substrate.

A carbon film removing process in which the carbon films included in the insulating film-carbon film laminate are removed.

An electrode film forming process in which a plurality of electrode films is formed in the regions where the carbon films are removed in the carbon film removing process to obtain an insulating film-electrode film laminate including the plurality of insulating films and the plurality of electrode films laminated in a plurality of layers.

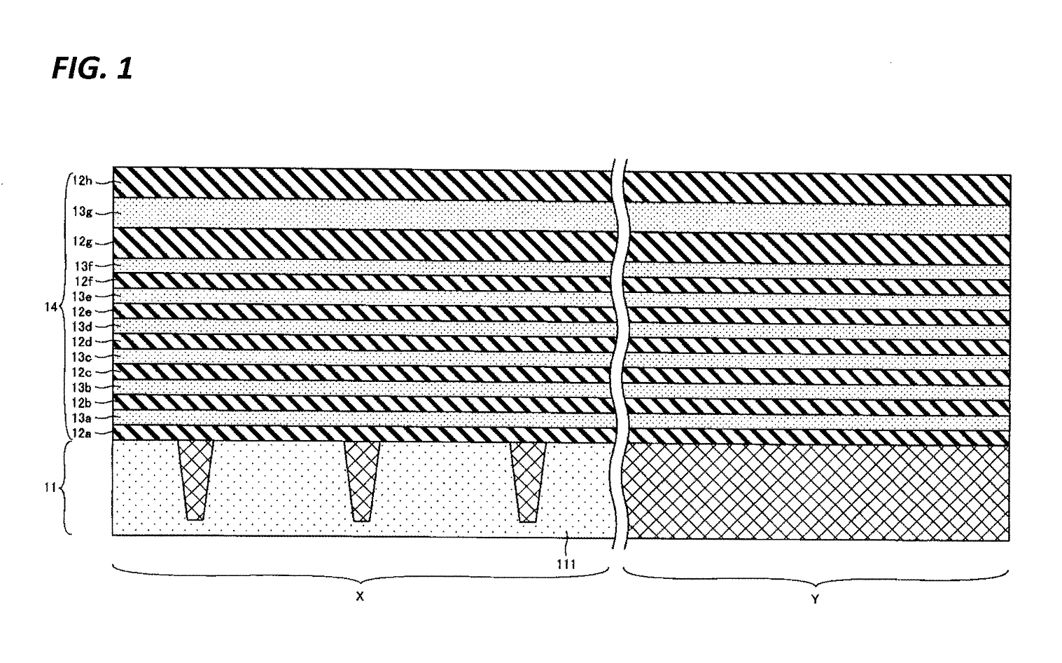

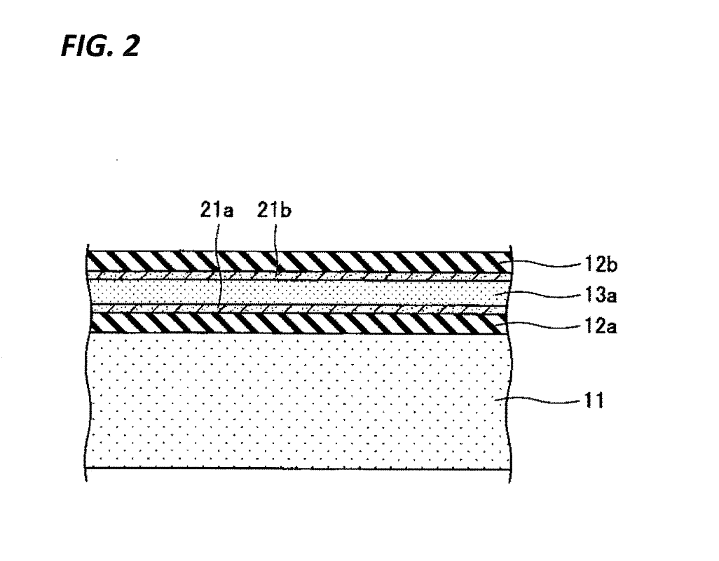

First, each of the insulating film forming process, the carbon film forming process, and the insulating film-carbon film laminate forming process will be described in detail with reference to FIGS. 1 and 2. FIG. 1 illustrates a cross-sectional view taken along a plane parallel to a lamination direction of an insulating film-carbon film laminate in a state where the insulating film-carbon film laminate is formed on the substrate after the insulating film-carbon film laminate forming process. FIG. 2 illustrates a view illustrating a part of FIG. 1 in an enlarged scale in a case where silicon films to be described later are formed.

Descriptions will be made on a substrate 11 adopted in the method of manufacturing the semiconductor device of the present exemplary embodiment. There is no particular limitation in the substrate 11, but, for example, a bulk single crystal substrate, or a single crystal SOI substrate may be used. When, for example, a semiconductor memory is formed, memory strings may be disposed on the substrate, and contacts for laminated word lines may be formed on any one end side of the substrate. Thus, as illustrated in FIG. 1, one part of the substrate 11 may be a memory string region X on which memory strings are disposed, and another part of the substrate 11 may be a word line contact region Y on which contacts of word lines is provided.

In the memory string region X where the memory strings are disposed, when impurities of a predetermined conductive type are implanted and activated, a source region 111 may be formed. The source region 111 may be formed in, for example, a p-type.

As necessary, for example, a peripheral circuit (not illustrated) may be formed on the word line contact region Y.

In the method of manufacturing the semiconductor device of the present exemplary embodiment, the insulating film forming process may be performed. An insulating film 12a may be formed on one side of the substrate 11. The insulating film 12a may be formed on the substrate 11 as a first layer. In addition, insulating films 12b to 12h, which are formed as layers subsequent to the first layer in the insulating film-carbon film laminate forming process, may be formed on carbon films 13a to 13g, respectively, as illustrated in FIG. 1.

A material for the insulating film 12a formed in the insulating film forming process is not particularly limited, but may be, for example, a silicon oxide film.

The insulating film 12a forming method is not particularly limited, but may be optionally selected according to, for example, a material of a film to be formed or a film thickness. When the insulating film 12a is a silicon oxide film, for example, a so-called chemical vapor deposition (CVD) method may be adopted in which a silicon-containing gas and an oxidizing agent-containing gas are simultaneously supplied to perform film formation. As the CVD method, for example, a thermal CVD method or a plasma CVD method may be used. The temperature for film formation may be optionally selected according to, for example, the kind of the silicon-containing gas used for the film formation, without any particular limitation. For example, the film formation may be performed at a temperature ranging from 300° C. to 800° C. Particularly, the film formation may be performed at a temperature ranging from 400° C. to 700° C.

When the silicon oxide film is formed as the insulating film 12a, besides the CVD method, a so-called atomic layer deposition (ALD) method or a molecular layer deposition (MLD) method may be adopted in which a silicon-containing gas and an oxidizing agent-containing gas are alternately supplied to perform film formation. For example, the ALD (or MLD) method may be a plasma ALD (or MLD) method or an ALD (or MLD) method, which is performed at a processing temperature ranging from room temperature (25° C.) to 400° C.

When the silicon oxide film is formed as the insulating film, the silicon-containing gas used for the insulating film forming process is not particularly limited. For example, various silane gases such as, for example, dichlorosilane, may be used. As the oxidizing agent, for example, N₂O (nitrous oxide) or oxygen may be used.

The film thickness of the insulating film 12a formed in the insulating film forming process may be optionally selected without any particular limitation. For example, the film may be formed to a film thickness ranging from 10 nm to 50 nm. Particularly, the film may be formed to a film thickness ranging from 20 nm to 40 nm.

The insulating films 12b to 12h formed in the insulating film-carbon film laminate forming process to be described later may be configured in the same manner as in the insulating film 12a. That is, the insulating films 12b to 12h may be made of the same material as that of the insulating film 12a, and formed by the same film-forming method and the same film-forming condition as those used for forming the insulating film 12a. Also, the film thickness of the insulating films 12b to 12h may have the same range as described above.

Next, the carbon film forming process will be described.

In the carbon film forming process, a carbon film 13a may be formed on the insulating film 12a formed in the insulating film forming process. Carbon films 13b to 13g formed as layers subsequent to the first layer in the insulating film-carbon film laminate forming process, may be formed on the insulating films 12b to 12g, respectively, as illustrated in FIG. 1. As the carbon films, for example, amorphous carbon films may be formed.

The carbon film 13a forming method is not particularly limited. For example, the carbon film 13a may be formed through a thermal CVD method or a plasma CVD method. Also, the carbon film 13a may be formed through a plasma ALD method or a plasma MLD method.

Conditions for the carbon film forming process, such as, for example, a temperature for film formation, are not particularly limited. The film formation temperature of the carbon film may range preferably from 500° C. to 900° C., more preferably from 600° C. to 800° C. This is because when the film formation temperature of the carbon film is set to, for example, 500° C. or more as described above, a sufficient heat resistance may be provided under a film formation condition (a film formation temperature), for example, in the insulating film forming process, or formation of channels of memory strings to be described later. Accordingly, in the insulating film-carbon film laminate forming process to be described later, it is possible to reduce the risk that the carbon film is damaged at a temperature used, for example, when forming the insulating film. However, when the film formation temperature is excessively high, the carbon film may not be formed, or an adverse effect may be caused in other members such as, for example, a substrate. Thus, the temperature may be set to preferably 900° C. or less, more preferably 800° C. or less.

A gas used for the carbon film forming process is not particularly limited. A carbon-containing gas, such as, for example, an ethylene (C₂H₄) gas or a propylene (C₃H₆) gas may be used.

The insulating film and the carbon film may have a low adhesion. Also, when the insulating film is additionally formed after the carbon film is formed, as described below, the film thickness of the carbon film may be reduced by the atmosphere during the formation of the insulating film.

Accordingly, a silicon film forming process may be further performed to form a silicon film before the carbon film forming process is performed and after the carbon film forming process is performed. That is, the silicon film forming process may be performed to form a silicon film (a seed layer) after the insulating film forming process before the carbon film forming process, and subsequently to the carbon film forming process.

In this case, for example, as illustrated in FIG. 2, the carbon film 13a is disposed on the insulating film 12a formed on the substrate 11 through a silicon film 21a, and the insulating film 12b is further disposed on the carbon film 13a through a silicon film 21b. Although the layers above the insulating film 12b are omitted in FIG. 2, when other carbon films are formed, silicon films may be disposed above and below the carbon films in the same manner as described above, that is, between the carbon films and the insulating films.

When the silicon films 21a and 21b are formed in this manner, adhesion between the insulating films 12a and 12b and the carbon film 13a may be improved.

When an insulating film is formed on the top surface of a carbon film, the film thickness of the carbon film is reduced. It is believed that this is caused since oxygen or oxygen radicals in the oxidizing agent used for forming the insulating film come in contact with the surface of the carbon film to form CO or CO₂ which is volatilized. Accordingly, when the silicon film 21b is disposed on the surface of the carbon film 13a, oxygen or oxygen radicals may be suppressed from directly coming in contact with the carbon film 13a. Thus, the volatilization of the carbon film 13a may be suppressed and the reduction in film thickness of the carbon film 13a may be suppressed.

In the silicon film forming process, a specific method of forming the silicon film is not particularly limited. For example, a thermal CVD method, a plasma CVD method, a plasma ALD method, or a plasma MLD method may be used.

Gas species used for forming the silicon film are not particularly limited. For example, an aminosilane-based gas may be used. As for the aminosilane-based gas, for example, butyl amino silane (BAS), bistertiarybutyl amino silane (BTBAS), dimethyl amino silane (DMAS), bisdimethylamino silane (BDMAS), tridimethyl amino silane (TDMAS), diethylamino silane (DEAS), bis-diethylamino silane (BDEAS), dipropylamino silane (DPAS), or diisopropylamino silane (DIPAS) may be used.

The heating temperature of the substrate at the time of forming the silicon film is not particularly limited. For example, the substrate may be heated to a temperature ranging from 300° C. to 900° C. More particularly, the substrate may be heated to a temperature ranging from 400° C. to 800° C.

The thickness of the silicon film is not particularly limited, but may be optionally selected according to, for example, a required adhesion between the insulating film and the carbon film, or an extent to which the reduction of a film thickness of the carbon film has to be suppressed. In particular, in order to increase the adhesion between the insulating film and the carbon film, and suppress the reduction of the film thickness of the carbon film at the time of forming the insulating film, the film thickness of the silicon film may be set to range from 0.1 nm to 1.0 nm. More particularly, the film thickness may be set to range from 0.2 nm to 0.7 nm.

Next, the insulating film-carbon film laminate forming process will be described.

In the insulating film-carbon film laminate forming process, the insulating film forming process described above and the carbon film forming process described above may be alternately and repeatedly performed. Accordingly, the insulating films 12b to 12h and the carbon films 13b to 13g may be laminated on the substrate 11 to form the insulating film-carbon film laminate 14 as illustrated in FIG. 1. The insulating film forming process and the carbon film forming process in the insulating film-carbon film laminate forming process may be performed in the sequence described above, and thus descriptions thereof will be omitted.

There is no limitation in the number of times of repeating the insulating film forming process and the carbon film forming process, but the insulating film framing process and the carbon film forming process may be repeated according to the required number of layers. Accordingly, although FIG. 1 illustrates an example in which seven (7) layers of carbon films and eight (8) layers of insulating films are laminated, the number of layers of respective films in the insulating film-carbon film laminate is not particularly limited. A plurality of layers may be further laminated. Also, the number of layers may be less than that in the case of FIG. 1.

However, as described below, the carbon films serve as sacrificial films when a semiconductor device is formed using the insulating film-carbon film laminate, and then the carbon films are removed. For this reason, the insulating film-carbon film laminate forming process may be performed so that the uppermost layer becomes the insulating film.

The method of manufacturing the semiconductor device of the present exemplary embodiment described above may form an insulating film-carbon film laminate. The carbon films may serve as sacrificial films, and may be removed by a dry removal means (a removal method). Thus, even when the sacrificial films are removed, the insulating films may be suppressed from being deflected as compared to a case in which the sacrificial films are removed by a wet method as in the conventional technology.

In the method of manufacturing the semiconductor device of the present exemplary embodiment, various processes may be further added to obtain a predetermined configuration of a semiconductor device. In the following description, specific examples will be described.

(Trench Forming Process)

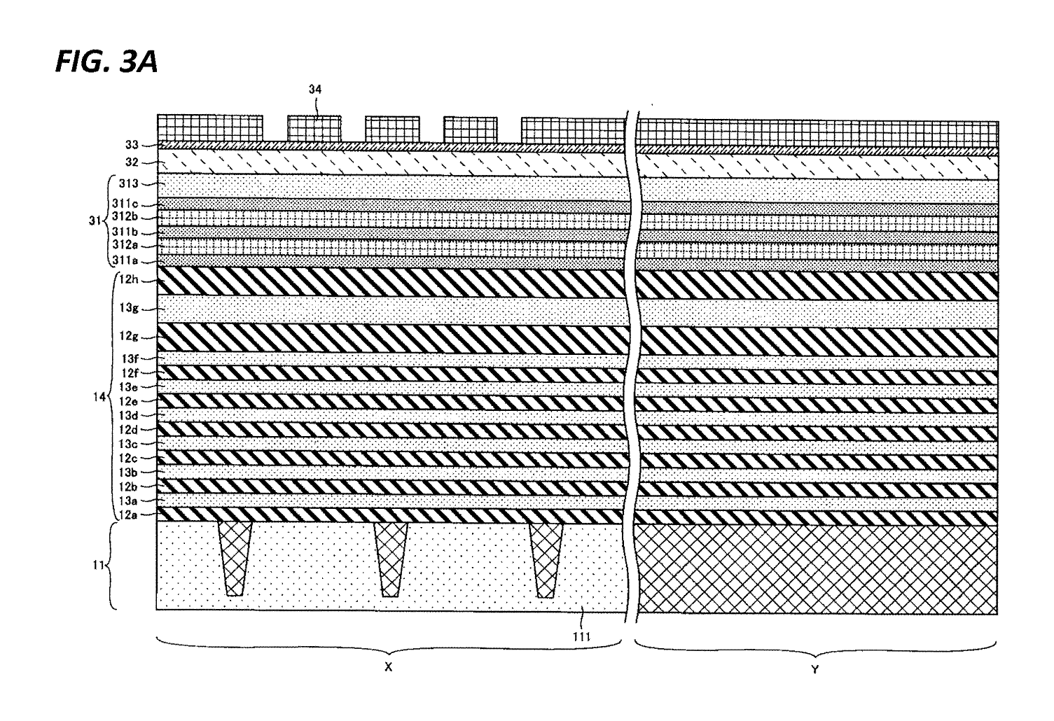

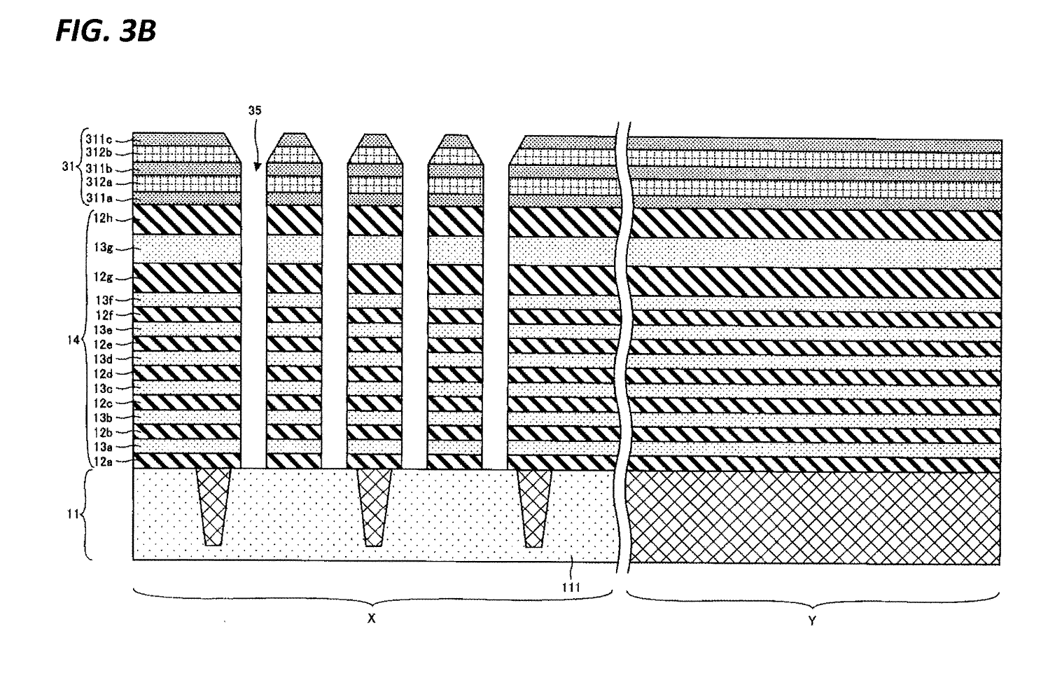

On the insulating film-carbon film laminate obtained by the semiconductor device manufacturing method described so far, a trench forming process including the following processes may be further performed to form trenches in which, for example, memory strings will be formed. The trench forming process will be described with reference to FIGS. 3A and 3B.

A hard mask film forming process for forming a plurality of hard mask films on an insulating film-carbon film laminate.

A insulating film and carbon film etching process for etching insulating films and carbon films using the hard mask films as a mask.

First, the hard mask film forming process will be described.

The hard mask film forming process refers to a process in which a hard mask film 31 serving as a mask is disposed when the insulating film and carbon film etching process to be described later is performed. For example, as illustrated in FIG. 3A, the hard mask film 31 may be disposed on the top surface of an insulating film-carbon film laminate 14.

The hard mask film 31 only has to be configured to serve as a mask in the insulating film and carbon film etching process to be described later, and the configuration of the hard mask film 31 is not particularly limited. The hard mask film 31 may include a first inorganic material layer, and a second inorganic material layer made of a material different from the material for the first inorganic material layer. When the hard mask film 31 includes the layers made of different materials, the layers made of different materials may serve as a stopper layer when, for example, chemical mechanical polishing (CMP) to be described later is performed.

As illustrated in FIG. 3A, the hard mask film 31, may include a plurality of first inorganic material layers 311a, 311b, and 311c and a plurality of second inorganic material layers 312a and 312b which are alternately formed. As illustrated in FIG. 3A, a third inorganic material layer 313 may be disposed in the hard mask film 31.

For example, in a case where a plurality of openings such as, for example, trenches with different depths, is formed in the insulating films and the carbon films, when the hard mask film 31 is formed each time etching is performed, the number of processes may be increased. Thus, as described above, when the plurality of first inorganic material layers and second inorganic material layers which are included in the hard mask film 31 are formed in advance according to the number of etching processes, the number of processes for forming the mask may be reduced.

The materials for the first inorganic material layers 311a to 311c and the second inorganic material layers 312a and 312b included in the hard mask film 31 are not particularly limited. For example, polysilicon or silicon nitride may be used. As described above, when the third inorganic material layer 313 is disposed, the third inorganic material layer 313 may be made of, for example, silicon oxide.

A mask layer used for etching may be further disposed on the hard mask film 31. The configuration of the mask layer is not particularly limited. For example, as illustrated in FIG. 3A, an organic mask film 32, a spin-on-glass (SOG) film 33, and a photoresist 34 may be disposed in this order from the hard mask film 31 side. In this case, when a desired pattern is formed on the photoresist 34 and then etching is performed, the pattern formed on the photoresist 34 is firstly transferred to the SOG film 33 and the organic mask film 32 below the photoresist 34. Then, when the etching is further performed, the pattern is transferred to the hard mask film 31, and then the insulating films and the carbon films of the insulating film-carbon film laminate 14 disposed below the hard mask film 31 may be etched, as illustrated in FIG. 3B. During the insulating film and carbon film etching process, the organic mask film 32, the SOG film 33, and the photoresist 34 are removed, and trenches 35 are formed in the insulating films and the carbon films. In the trenches 35, memory strings will be formed as described below.

The shape of each of the trenches 35 is not particularly limited, but may have, for example, a cylindrical shape. The bottom surface of each of the trenches 35 may be the top surface of the substrate 11.

FIG. 3B illustrates a cross-sectional view of the semiconductor device according to the present exemplary embodiment, taken along a plane passing through the centers of the trenches 35 arranged in a direction parallel to the paper sheet. The trenches 35 may also be arranged at a plurality of locations at predetermined intervals in a direction perpendicular to the paper sheet in FIG. 3B.

Conditions for performing the etching are not particularly limited as long as the insulating films and the carbon films included in the insulating film-carbon film laminate 14 may be etched.

Specifically, for example, plasma etching may be performed.

As for a gas used for performing the plasma etching, for example, a gas obtained by adding any gas selected from SF₆, CF₄, and NF₃, Ar, and O₂ to C₄F₈, may be used. Also, a mixed gas of CF₄ and H₂ may be used. When the plasma etching is performed using these gases, the insulating films and the carbon films may be simultaneously etched.

A gas capable of etching the insulating films and a gas capable of etching the carbon films may be alternately supplied to perform the etching. For example, when the insulating films are etched, a gas obtained by adding Ar and O₂ to CF₄F₈ or C₄F₆ may be used, and when the carbon films are etched, a mixed gas of O₂ and carbonyl sulfide (COS), or a mixed gas of O₂, N₂, and H₂ may be used.

The conditions for performing the plasma etching are not particularly limited. For example, the plasma etching may be performed at a gas pressure ranging from 10 mTorr to 50 mTorr, with a power output ranging from 1000 W to 2000 W, and a bias output ranging from 2000 W to 4000 W.

(Memory String Forming Process)

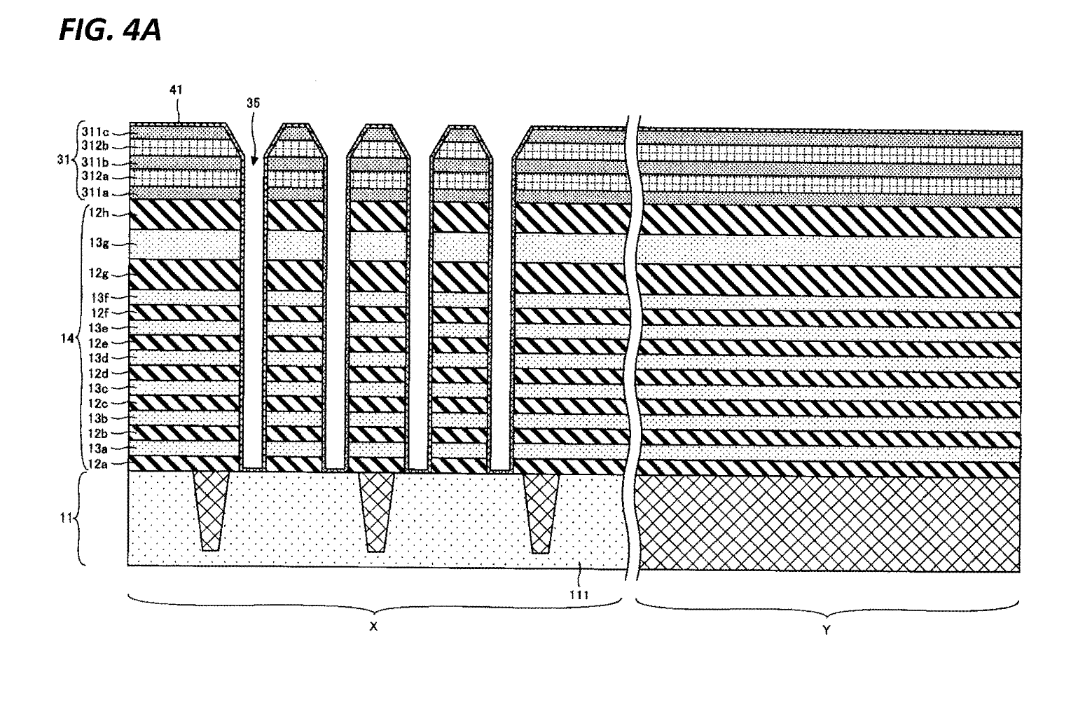

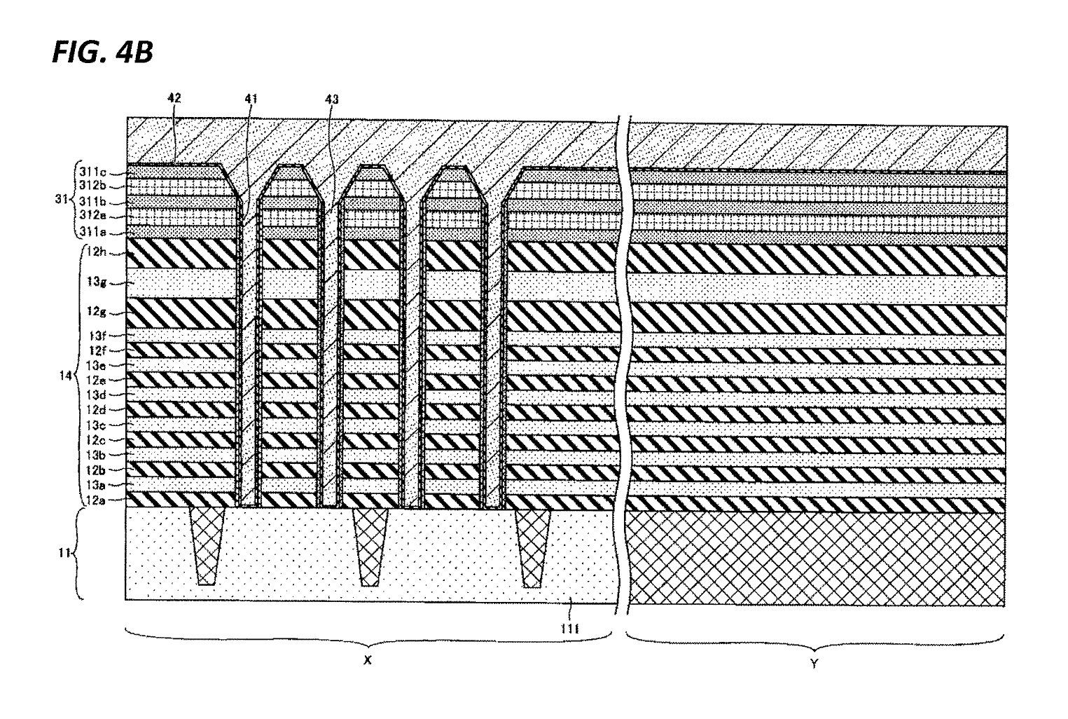

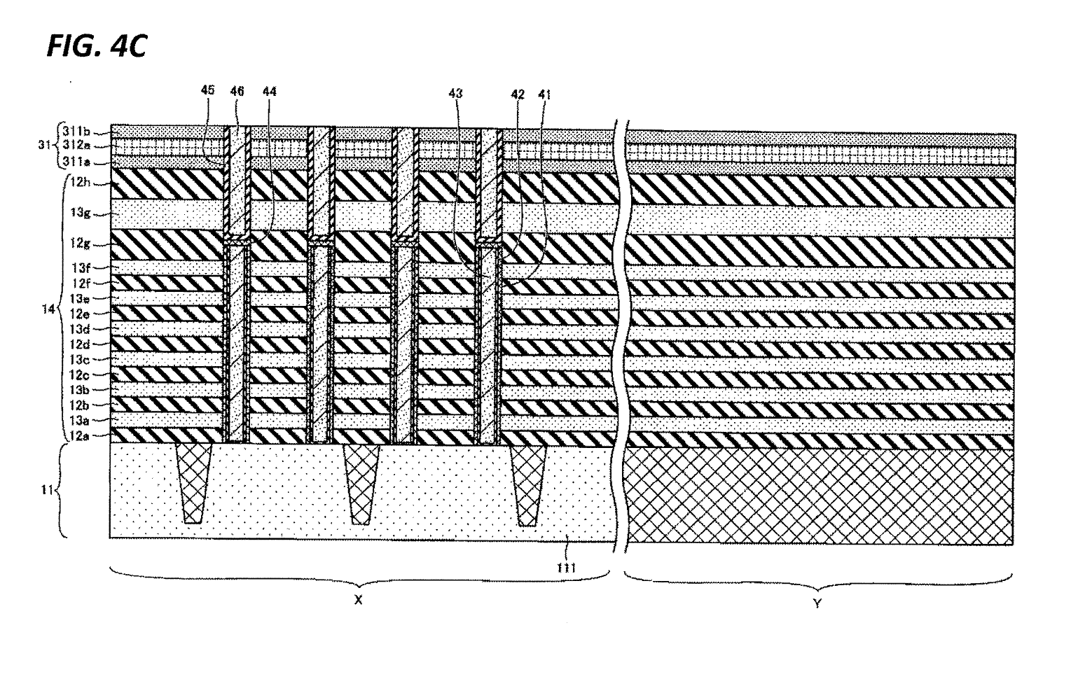

In the method of manufacturing the semiconductor device of the present exemplary embodiment, a memory string forming process may be performed to sequentially form members constituting the memory strings within the trenches 35 formed in the insulating film-carbon film laminate 14. The memory string forming process will be described with reference to FIGS. 4A to 4C.

In the memory string forming process, for example, following processes may be performed.

An inter-gate dielectric (IGD) film and charge trap film forming process for forming an IGD film and a charge trap film on the surface of each of the trenches 35.

An IGD film and charge trap film removing process for removing the IGD film and the charge film formed on the bottom surface of each of the trenches 35.

A tunnel oxide film forming process for forming a tunnel oxide film on the surface of the IGD film and the charge trap film.

A channel forming process for forming channel portions of memory strings within the trenches 35.

A hard mask film removing process for removing a part of the hard mask film 31.

A selection gate forming process for forming selection gates.

Hereinafter, the respective processes will be described.

The IGD film and charge trap film forming process may be performed by forming an IGD film and a charge trap film which are laminated in this order on the surface of each of the trenches 35 and the top surface of the hard mask film 31, as illustrated in FIG. 4A.

The IGD film is not particularly limited, but an insulating film with a high dielectric constant (high-K) may be used. For example, an ONO film (a laminated structure film of a silicon oxide film/a silicon nitride film/a silicon oxide film), or a laminated structure film of SiO₂ film and HfO₂ film may be used.

As for the charge trap film, for example, a silicon nitride film may be used.

A method of forming the IGD film and the charge trap film is not particularly limited. For example, a CVD method, an ALD method, or a MLD method may be used.

In the IGD film and charge trap film forming process, as illustrated in FIG. 4A, an IGD film-charge trap film laminate 41 is also formed on the bottom surface of each of the trenches 35. Thus, an IGD film and charge trap film removing process may be performed to remove the IGD film-charge trap film laminate 41 formed on the bottom surface of each of the trenches 35. The IGD film and charge trap film removing process may be performed by, for example, anisotropic etching. Here, the IGD film-charge trap film laminate 41 formed on the top surface of the hard mask film 31 is also removed.

Then, as illustrated in FIG. 4B, a process of forming a tunnel oxide film 42 on the surface of the IGD film-charge trap film laminate 41 may be performed. The tunnel oxide film may be, for example, a silicon oxide film or a silicon nitride film. The tunnel oxide film 42 is also formed on the bottom surface of each of the trenches 35 but has an insignificant influence on current. Thus, the tunnel oxide film 42 formed on the bottom surface may be removed or the subsequent process may be performed without removing the tunnel oxide film 42.

A method of forming the tunnel oxide film is not particularly limited. For example, a CVD method, an ALD method, or a MLD method may be used.

Then, as illustrated in FIG. 4B, a channel forming process may be performed to form a channel portion of a memory string in a region surrounded by the tunnel oxide film 42 within each of the trenches 35. A material for channels 43 is not particularly limited. For example, polysilicon may be used.

A method of forming the channels is not particularly limited. For example, a CVD method, an ALD method or a MLD method may be used.

As illustrated in FIG. 4B, when the channels 43 are formed in the channel forming process, a layer of a material for the channels 43 is formed not only within the trenches 35, but also on the top surface of the hard mask film 31. Accordingly, after the channel forming process, a hard mask film removing process may be performed to remove the layer of the channel material formed on the top surface of the hard mask film 31, and a part of the hard mask film 31.

A part of the hard mask film 31 may be used as a mask when an insulating film is formed between selection gates as described below. Thus, the hard mask film 31 may not be completely removed. For example, among the first inorganic material layers and the second inorganic material layers constituting the hard mask film 31, the first inorganic material layer and the second inorganic material layer disposed on the outermost surface may be removed. For example, in the case of FIG. 4B, the first inorganic material layer 311c and the second inorganic material layer 312b may be removed.

A method of removing a part of the hard mask film 31, and the layer of the channel material formed on the top surface of the hard mask film 31 is not particularly limited. For example, CMP may be used.

Then, the selection gate forming process may be performed to form selection gates.

In a case where a semiconductor memory is manufactured as the semiconductor device, when the carbon films are replaced by electrodes, an electrode of the uppermost layer may become a selection gate electrode. The other electrode portions may become word lines. Thus, the selection gate forming process may be performed on the portions of memory strings which correspond to the carbon film 13g of the uppermost layer to form selection gates.

The selection gate forming process is not particularly limited. For example, the following processes may be performed to form the selection gates illustrated in FIG. 4C.

A selection gate forming region removing process for removing the channels 43, the IGD films, the charge trap films, or the tunnel oxide films 42 from the portions of the memory strings where selection gates will be formed.

A source region forming process for forming a source region 44 by doping, for example, arsenic on the exposed top surface of each of the channels 43.

An oxide insulating film forming process for forming oxide insulating films (SiO₂ films) 45 on the surfaces of the regions from which, for example, the channels 43 are removed.

A selection gate channel forming process for forming channels 46 of the selection gates in cavities within the oxide insulating films 45 formed in the oxide insulating film forming process.

A drain region forming process for forming a drain region by doping, for example, arsenic on the top surface of each of the formed channels 46 of the selection gates. Since it is preferable that the drain region faulting process is performed after, for example, the carbon film removing process to be described below, the drain region is not illustrated in FIG. 4C.

A method for a selection gate forming region removing process is not particularly limited. For example, etching may be performed.

The oxide insulating film formed in the oxide insulating film forming process is not particularly limited. For example, a silicon oxide film (SiO₂) may be used. A method for forming the oxide insulating film is not particularly limited. For example, a CVD method, an ALD method or a MLD method may be used.

The selection gate channel forming process may be performed in the same manner as, for example, in the channel forming process described above in which the channels 43 are formed.

The selection gate forming process is not limited to the above described processes. For example, when the regions where the selection gates will be formed are not formed with, for example, the IGD films or the channels 43 in advance but remain as cavities, the drain region forming process may be performed first without performing the selection gate forming region removing process.

The memory string forming process may be performed after the electrode forming process to be described below. However, the electrode forming process refers to a process for forming electrodes in the cavities formed when carbon films are removed, and when the memory string forming process has been already performed, the memory strings act to support the insulating films remaining after the carbon films are removed. Thus, when the memory string forming process is performed after the electrode forming process, insulating film supporting members may be formed, instead of the memory strings after the trench forming process. That is, instead of the memory string forming process, an insulating film supporting member forming process may be performed after the trench forming process.

As for the insulating film supporting members to be formed instead of the memory strings, for example, trenches filled with silicon nitride may be used. Thus, for example, a filling process for filling the trenches with silicon nitride may be performed after the trench forming process in which the trenches are formed through the insulating films and carbon films of the insulating film-carbon film laminate. Accordingly, the silicon nitride filled in the trenches may support the insulating films remaining after the carbon films are removed so that the cavities of the insulating films may be maintained. The trench forming process may be performed by the method described above.

After the above described process, the memory strings may be formed after the silicon nitride is removed. In this manner, when the memory string forming process is performed after the electrode forming process, the IGD films or the charge trap films included in the memory strings may be particularly suppressed from being damaged when the carbon films are removed in the electrode forming process.

FIGS. 4A to 4C illustrate cross-sectional views of the semiconductor device according to the present exemplary embodiment, taken along a plane passing through the centers of the trenches 35 arranged in a direction parallel to the paper sheet, in which memory strings are formed in the trenches 35. Then, in the semiconductor device of the present exemplary embodiment, as described above, the trenches 35 may also be arranged at a plurality of locations at predetermined intervals in a direction perpendicular to the paper sheet. Accordingly, in the memory string forming process illustrated in FIGS. 4A to 4C, the memory strings may also be formed in the trenches 35 (not illustrated) formed in the direction perpendicular to the paper sheet.

(Electrode Forming Process and Insulating Film Forming Process Between Memory Strings)

In the method of manufacturing the semiconductor device of the present exemplary embodiment, as described above, a carbon film removing process and an electrode film forming process may be performed as described below.

When the carbon film removing process and the electrode film forming process are performed as described below, the carbon films 13a to 13g serving as sacrificial films may be removed to form electrodes (an electrode forming process).

A carbon film removing process for removing the carbon films 13a to 13g included in the insulating film-carbon film laminate 14.

An electrode film forming process for forming electrode films in the regions remaining after the carbon films are removed in the carbon film removing process to obtain an insulating film-electrode film laminate in which the insulating films and the electrode films are laminated in a plurality of layers.

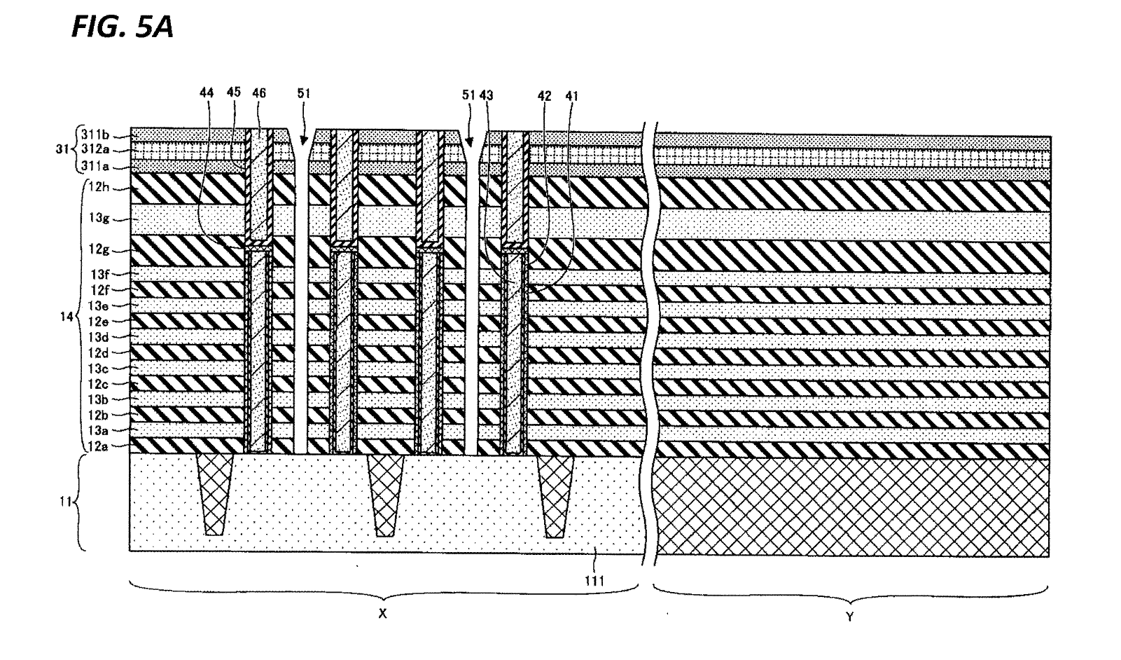

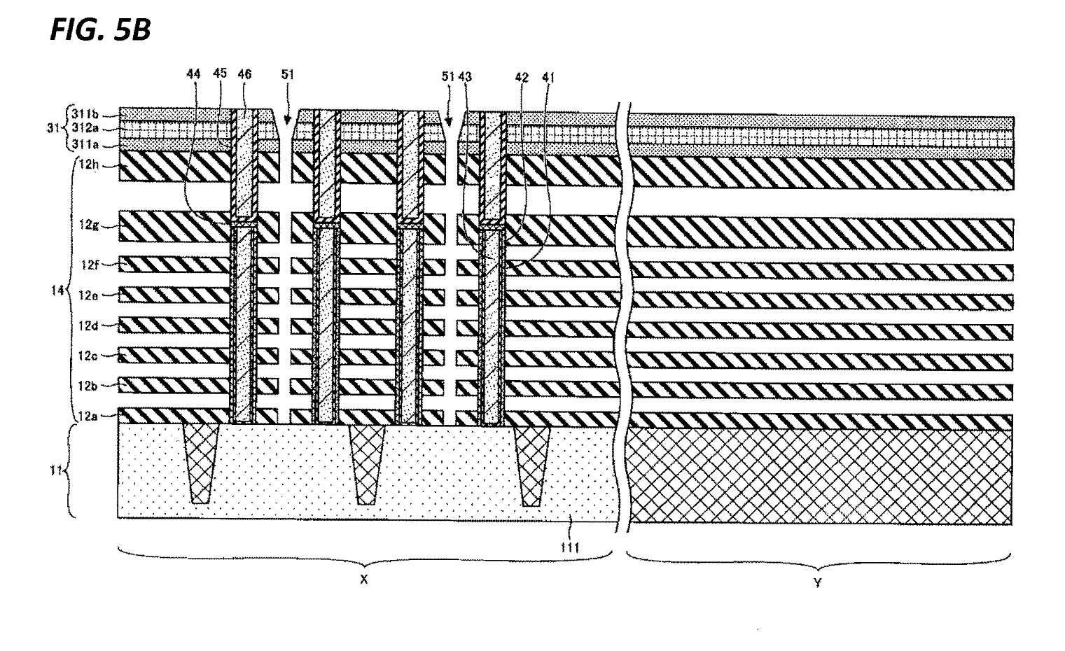

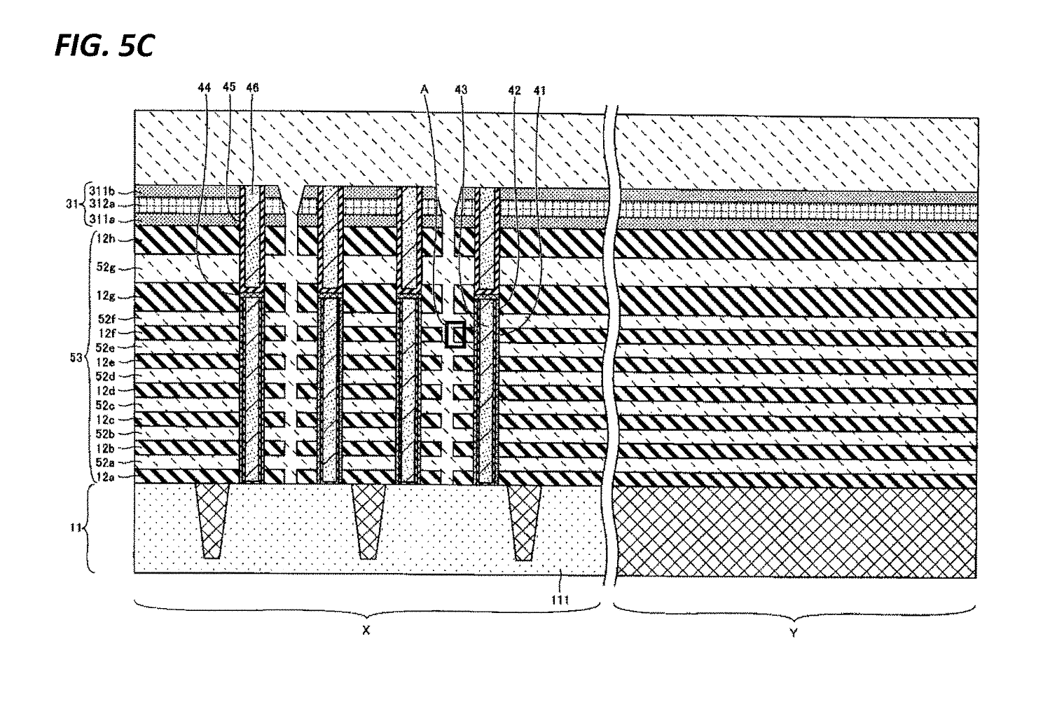

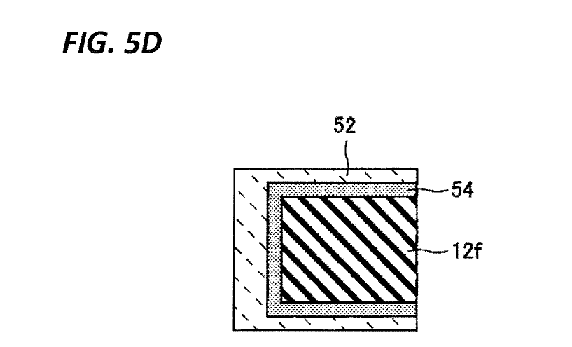

Respective processes will be described with reference to FIGS. 5A to 5D.

The carbon film removing process may be performed using a dry removal means (a sacrificial film removal means). Here, openings may be formed in the insulating film-carbon film laminate so as to supply the dry removal means, for example, oxygen plasma, to the carbon films. Accordingly, openings to be formed with the insulating films for insulating the memory strings from each other may be formed, as described below. The openings may be used for supplying oxygen plasma to the carbon films.

First, openings 51 to be formed with the insulating films for insulating the memory strings from each other may be formed, as illustrated in FIG. 5A.

The openings 51 to be formed with the insulating films for insulating memory strings from each other may be formed, for example, in the same manner as that used for forming the trenches 35. Specifically, an organic mask film, an SOG film and a photoresist may be disposed on the top surface of the remaining hard mask film 31, and etching may be performed. There is no need to dispose each of the opening 51 between every two memory strings. For example, as illustrated in FIG. 5A, each of the openings 51 only has to be formed between two memory strings connected via the source region 111 formed on the substrate 11. In this case, the openings 51 may be formed through all the layers in the insulating film-carbon film laminate 14, as illustrated in FIG. 1. Since the memory strings may be arranged in the direction perpendicular to the paper sheet, the openings 51 may also be formed over the entire semiconductor device in the direction perpendicular to the paper sheet.

Then, the carbon film removing process may be performed to remove the carbon films 13a to 13g included in the insulating film-carbon film laminate 14. When the carbon film removing process is performed, the carbon films 13a to 13g disposed between the insulating films 12a to 12h are removed to leave cavities, as illustrated in FIG. 5B. Since the insulating films 12a to 12h are supported by the formed memory strings, the interlayer cavities between the insulating films 12a to 12h are maintained.

A specific method of the carbon film removing process is not particularly limited. For example, the carbon film removing process may be performed by an ashing processing using oxygen plasma. In the case where a silicon film forming process was performed before and after the carbon film forming process, it is preferable that the formed silicon film has a composition of a silicon oxide film or a composition close to the silicon oxide film when the carbon film removing process is performed. This is because when the silicon film has a composition of the silicon oxide film or a composition close to the silicon oxide film, the dielectric constant may be reduced. Thus, it is preferable that the silicon film is oxidized in the carbon film removing process.

When an ashing processing using oxygen plasma is performed in the carbon film removing process as described above, the above-described silicon films formed before and after the carbon film forming process was performed may be oxidized in the process of performing the processing. Separately from the carbon film removing process, a silicon film oxidizing process may be provided to oxidize the silicon films.

When some residue of the carbon film is produced in the carbon film removing process, wet washing using a solution having a weak surface tension may be used in combination. In this case, the wet washing may be performed in a short time by using the solution having the weak surface tension. Thus, the insulating films may be suppressed from being deflected.

After the carbon film removing process, an electrode film forming process may be performed, in which electrode films are formed in the regions where the carbon films have been removed in the carbon film removing process so as to form an insulating film-electrode film laminate in which the insulating films and the electrode films are laminated in a plurality of layers. Accordingly, as illustrated in FIG. 5C, an insulating film-electrode film laminate 53 may be obtained in which electrode films 52a to 52g are formed between the insulating films 12a to 12h.

It is preferable that a titanium nitride film serving as a barrier film may be formed on the surface of each of the insulating films 12a to 12h before the electrode films 52a to 52g are formed. Thus, as illustrated in FIG. 5D which illustrates a region A of FIG. 5C in an enlarged scale, the electrode film 52 may be formed on the surface of the insulating film 12f through the titanium nitride film 54.

The electrode films 52a to 52g formed in the electrode film forming process are not particularly limited, but may be, for example, tungsten-containing films. Specifically, for example, tungsten or tungsten nitride may be used.

A method of forming the electrode film 52 and the titanium nitride film 54 is not particularly limited. For example, a CVD method, an ALD method, or a MLD method may be used for formation. Especially, the CVD method may be preferably used for forming the electrode film 52 and the titanium nitride film 54.

When the electrodes are formed by the electrode film forming process, a material constituting the electrodes is disposed on the top of the hard mask film 31 as well as within the openings 51 to be formed with the insulating films for insulating memory strings from each other, as illustrated in FIG. 5C. Thus, a process of removing the electrode material from portions which do not require electrodes may be performed.

The electrode material on the hard mask film 31 may be removed by, for example, CMP. Here, a part of the hard mask film 31 may also be removed. However, it is preferable that the first inorganic material is left since, for example, the first inorganic material layer 311a may be used as a mask when openings for disposing insulating films therein between the selection gates are formed as described below.

It is desirable to remove the electrode material disposed within the openings 51 to be formed with the insulating films for insulating the memory strings from each other by etching. Here, as in FIG. 3A, for example, a mask layer including an organic mask film, an SOG film, and a photoresist provided with openings corresponding to the openings 51 may be disposed on the top surface of the remaining hard mask film 31 (311a) to perform etching.

Then, a process of forming insulating films between memory strings may be performed by the following sequence.

First, in connection with the selection gates, each of the insulating films may be formed between every two selection gates. Thus, an opening to be formed with an insulating film for insulating the selection gates from each other may be formed in an area where selection gates face each other between memory strings which are not formed with the opening 51. The process for forming the openings is the same as that for forming the openings 51 to be formed with the insulating films for insulating the memory strings from each other, and thus description thereof will be omitted. The insulating films between the selection gates only have to be formed to insulate the electrode film 52g which becomes the selection gate electrodes. Thus, openings to be formed with the insulating films for insulating the selection gates from each other may be formed to, for example, a depth reaching the depth of the insulating film 12g illustrated in FIG. 5C.

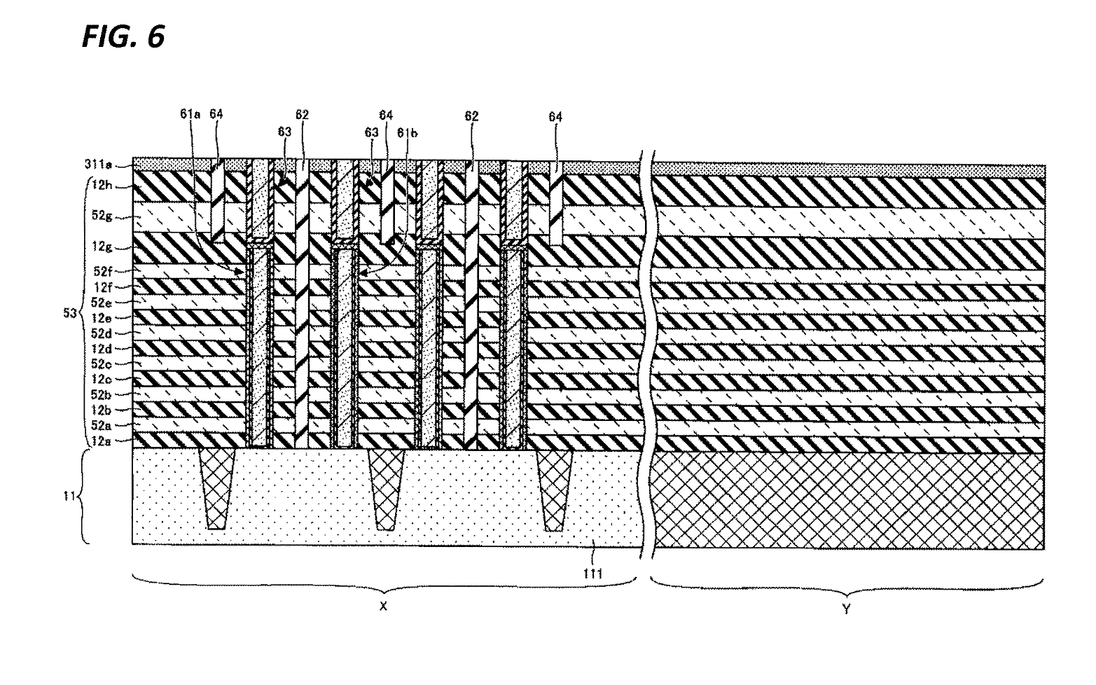

Insulating films 62 and insulating films 64 may be formed in the openings 51 to be formed with the insulating films for insulating the memory strings from each other, and in the openings to be formed with the insulating films for insulating the selection gates from each other, respectively. Accordingly, as illustrated in FIG. 6, the insulating films 62 are disposed between memory strings 61a and 61b connected via the source region 111 formed on the substrate 11, and the insulating films 62 and 64 are alternately disposed between the selection gates 63.

A material for the insulating films 62 and 64 is not particularly limited. For example, the insulating films 62 and 64 may be formed of a silicon oxide film.

As described above, in the semiconductor device of the present exemplary embodiment, for example, a plurality of memory strings with the same configuration as that of the memory strings illustrated in FIG. 6 is arranged at predetermined intervals in the direction perpendicular to the paper sheet of FIG. 6. Accordingly, the insulating films 62 and 64 may be formed within the semiconductor device over the direction perpendicular to the paper sheet of FIG. 6.

As described above, when a filling process for filling trenches with, for example, silicon nitride is performed as an insulating film supporting member forming process without performing the memory string forming process, the memory string forming process may be performed after the electrode forming process is performed.

Specifically, a process of removing the silicon nitride filled in the trenches, and the memory string forming process may be performed. The silicon nitride may be removed by, for example, etching. The memory string forming process may be performed by the sequence described above, and thus the descriptions thereof will be omitted.

(Word Line Contact Forming Process and Word Line Contact Insulating Film Forming Process)

In the method of manufacturing the semiconductor device of the present exemplary embodiment, a word line contact forming process may be performed to provide contacts of word lines in the word line contact region Y. In the word line contact forming process, the insulating films and the electrode films may be etched in a stepwise form, and may include, for example, each of the following processes.

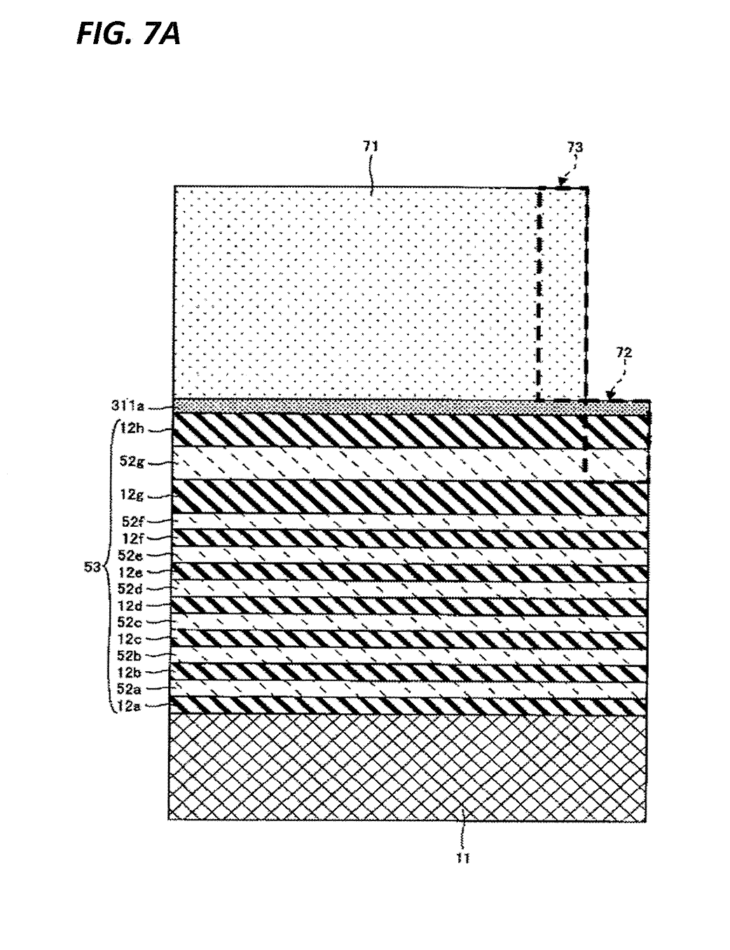

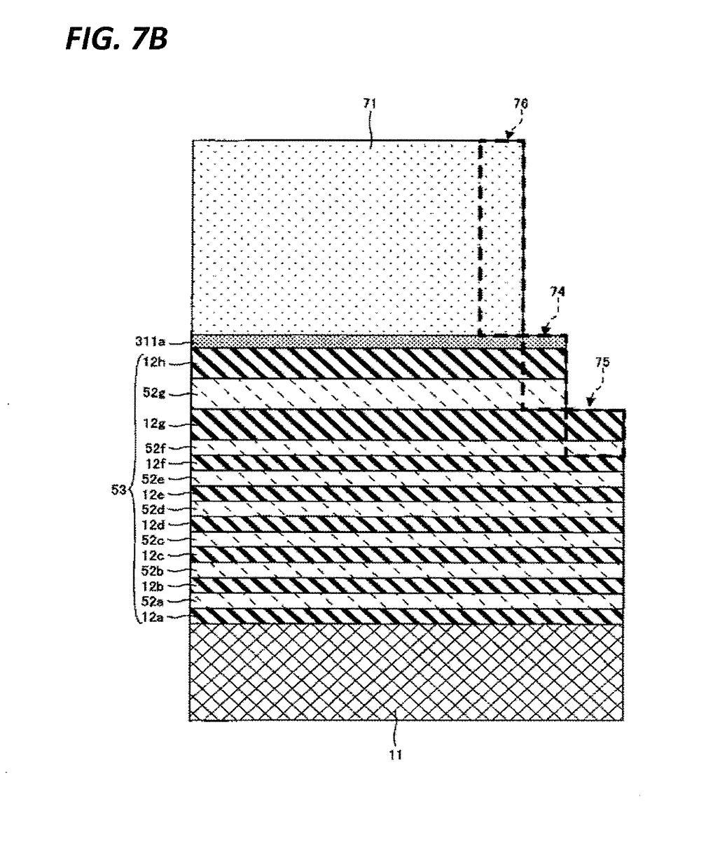

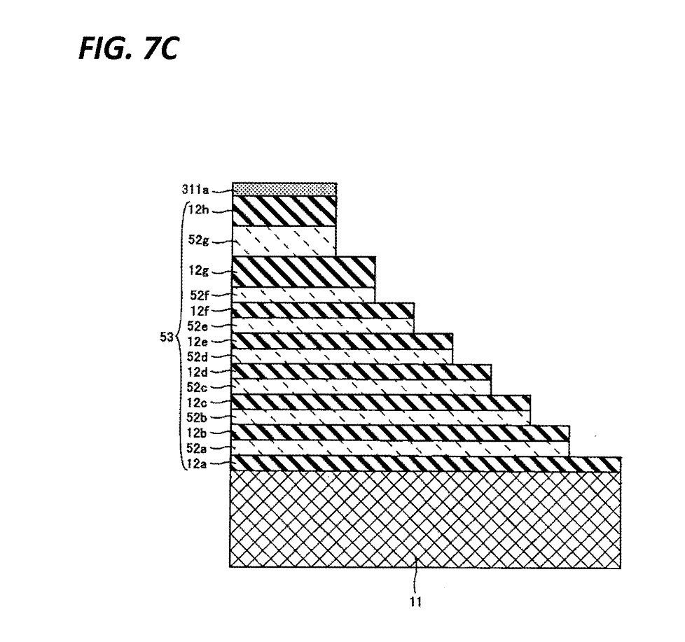

First, as illustrated in FIG. 7A, a mask disposing process is performed to dispose a mask 71 on the insulating film-electrode film laminate 53 through the hard mask film 31 (311a). Here, the mask 71 is formed so that the hard mask film 311a disposed on the insulating film-electrode film laminate 53 is exposed by an extent to which the insulating film and the electrode film are etched in the subsequent etching process.

When a trimming process is repeatedly performed to remove a part of the mask 71 as described below, the thickness of the mask 71 is also gradually reduced. Thus, the mask 71 may be formed to a sufficient thickness in consideration of, for example, the number of repetitions of the trimming process. A material for the mask 71 is not particularly limited. However, it is preferable that the mask 71 is not etched when the insulating film or the electrode film is etched. Thus, as for the mask 71, an organic mask formed of, for example, a photoresist, may be used.

FIGS. 7A and 7B illustrate only the word line contact region Y. However, the mask may also be disposed on the entire surface on the insulating film-electrode film laminate 53 in the memory string region X so that the insulating film or the electrode film formed in the memory string region X is suppressed from being etched in, for example, the etching process to be described below.

Then, an insulating film-electrode film etching process is performed by anisotropic etching to remove an etching region 72 exposed from the mask 71 and surrounded by a dotted line in the drawing in the insulating film 12h and the electrode film 52g of the uppermost layers of the insulating film-electrode film laminate 53. Here, the hard mask film 311a within the etching region 72 is also removed by etching.

A trimming process is performed by isotropic etching in which a trimming region 73 of the mask 71, which is surrounded by a dotted line, is removed so as to form a step. After the trimming process, the state illustrated in FIG. 7B is obtained.

Then, a repetition process is performed to alternately repeat the insulating film-electrode film etching process and the trimming process may be performed.

For example, in the state illustrated in FIG. 7B, etching may be performed in the same manner as in the etching process as described above to remove etching regions 74 and 75. Then, the trimming process may be performed to remove a trimming region 76 in the mask 71.

When the repetition process is performed, for example, an end portion of the insulating film-electrode film laminate 53 may be processed in a stepwise form to form word line contacts, as illustrated in FIG. 7C.

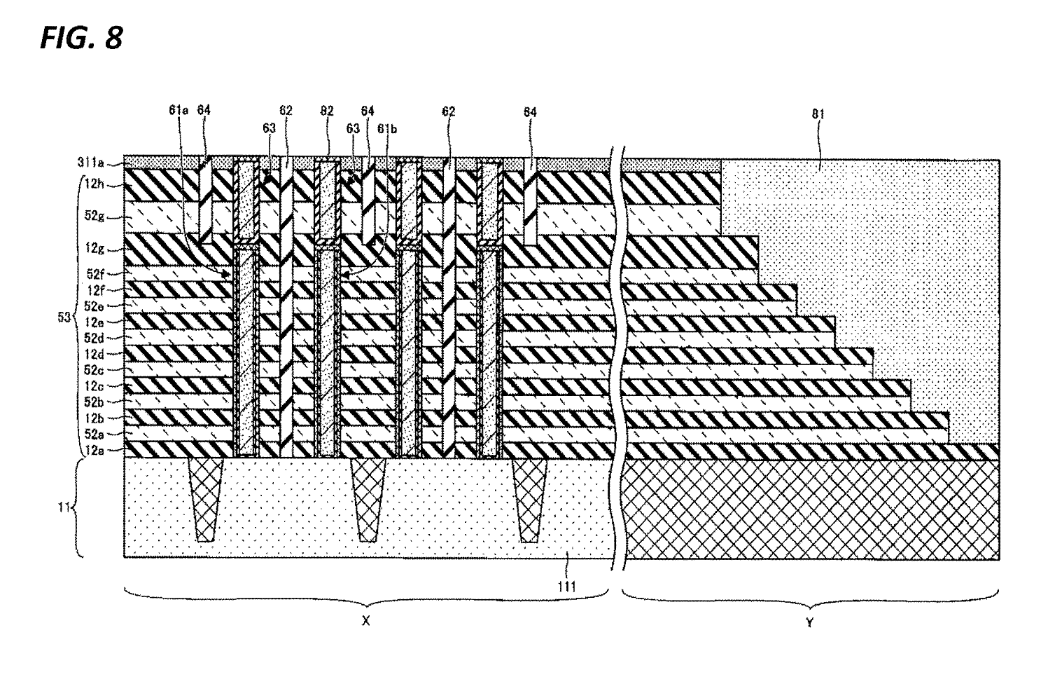

Then, a word line contact insulating film forming process may be performed to dispose an insulating film 81 on the end portion of the insulating film-electrode film laminate 53, which has been processed in the stepwise form. The exemplary configuration of the semiconductor device after the insulating film 81 is formed is illustrated in FIG. 8.

A material for the insulating film 81 is not particularly limited, but may be, for example, a silicon oxide film. The insulating film 81 may be formed by, for example, a CVD method.

When the insulating film 81 is formed, the insulating film 81 may be formed on the entire top side of the insulating film-electrode film laminate 53 as well as on the end portion processed in the stepwise form. In this case, the insulating film formed on the insulating film-electrode film laminate 53 may be removed by, for example, CMP. Accordingly, as illustrated in FIG. 8, the hard mask film 31 (311a) on the insulating film-electrode film laminate 53 may be exposed so that the hard mask film 31 (311a) on the insulating film-electrode film laminate 53 and the top surface of the insulating film 81 may be positioned on the same plane.

After the insulating film 81 is formed, as illustrated in FIG. 8, the top surfaces of the selection gates 63 are exposed. Thus, as described in the memory string forming process, the drain region forming process may be performed so that, for example, arsenic is doped on the top surfaces of the selection gate channels to form drain regions 82.

Processes for forming various members required for the semiconductor device may be further performed.

For example, a bit line forming process may be performed to form bit lines on the respective memory strings. FIG. 8 illustrates a cross-sectional view of the semiconductor device illustrated according to the present exemplary embodiment. A plurality of memory strings may be arranged at predetermined intervals in the direction perpendicular to the paper sheet in FIG. 8. In the bit line forming process, the bit lines may be formed on the top side of the memory strings to connect the memory strings arranged in the direction perpendicular to the paper sheet.

A word line wiring forming process may be performed on the word line contacts formed in the stepwise form so as to form wirings for word lines. The wirings for word lines may be formed substantially vertically with respect to, for example, respective electrodes included in the insulating film-electrode film laminate 53 in the word line contact forming region Y in FIG. 8. The word line wiring forming process may be performed by forming openings in a predetermined shape in advance in, for example, the insulating film 81 and the insulating films of the insulating film-electrode film laminate 53, and disposing a conductive material, for example, tungsten or tungsten nitride, in the openings.

So far, the method of manufacturing the semiconductor device of the present exemplary embodiment has been described. In the method of manufacturing the semiconductor device, the carbon films serving as the sacrificial films may be removed by a dry removal means after the insulating film-carbon film laminate is formed. Thus, the insulating films may be suppressed from being deflected and as a result, the yield may be improved.

In the present exemplary embodiment, the configuration of the NAND-type flash memory having a three-dimensional structure has been described as an example, but the present disclosure is not limited thereto. For example, the semiconductor device may be a ReRAM.

### Second Exemplary Embodiment

For example, before the electrode forming process and the insulating film forming process for forming insulation films between memory strings in the first exemplary embodiment, a word line contact forming process and a word line contact insulating film forming process may be performed. In such a case, an exemplary configuration of a method of manufacturing the semiconductor device will be described.

Until the memory strings are formed in the insulating film-carbon film laminate 14 as illustrated in FIG. 4C, the same processes as those in the first exemplary embodiment may be performed and thus descriptions thereof will be omitted.

Then, a process of forming word line contacts and a word line contact insulating film on the insulating film-carbon film laminate 14 having the memory strings thereon as illustrated in FIG. 4C will be described.

(Word Line Contact Forming Process and Word Line Contact Insulating Film Forming Process)

As in the first exemplary embodiment, a word line contact forming process may be performed to provide word line contacts in the word line contact region Y. In the present exemplary embodiment, instead of the insulating film-electrode film laminate, an end portion of the insulating film-carbon film laminate is processed in a stepwise form.

The word line contact forming process may have the following processes so that the insulating films and the carbon films which are laminated on top of each other are processed in a stepwise form at the end portion of the insulating film-carbon film laminate.

A mask disposing process for disposing a mask on the insulating film-carbon film laminate.

An insulating film etching process for removing a part of the insulating film.

A trimming process for removing a part of the mask and the carbon film.

A repetition process for alternately repeating the insulating film etching process and the trimming process.

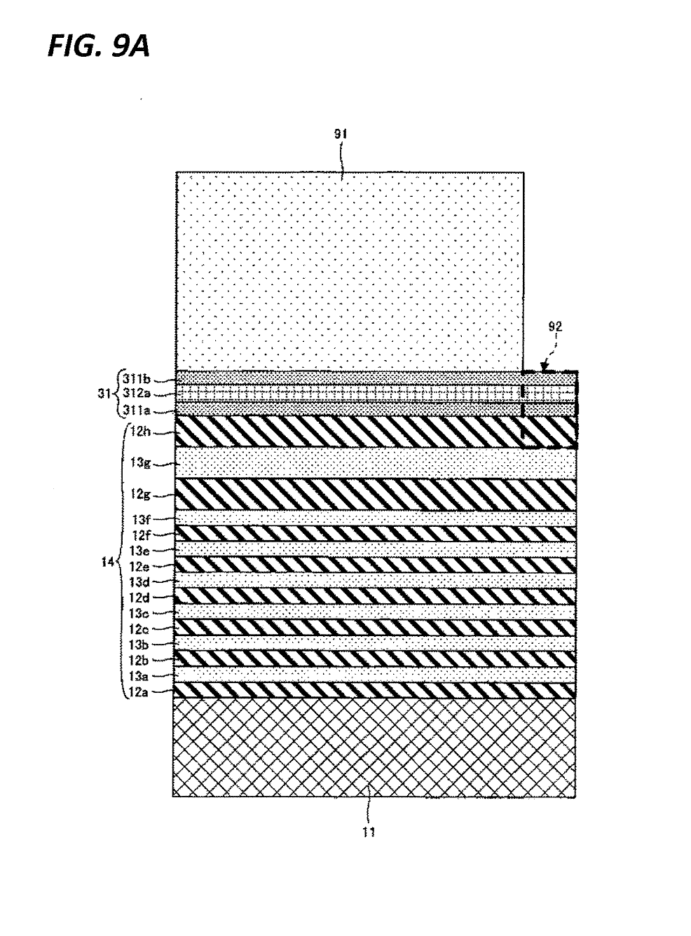

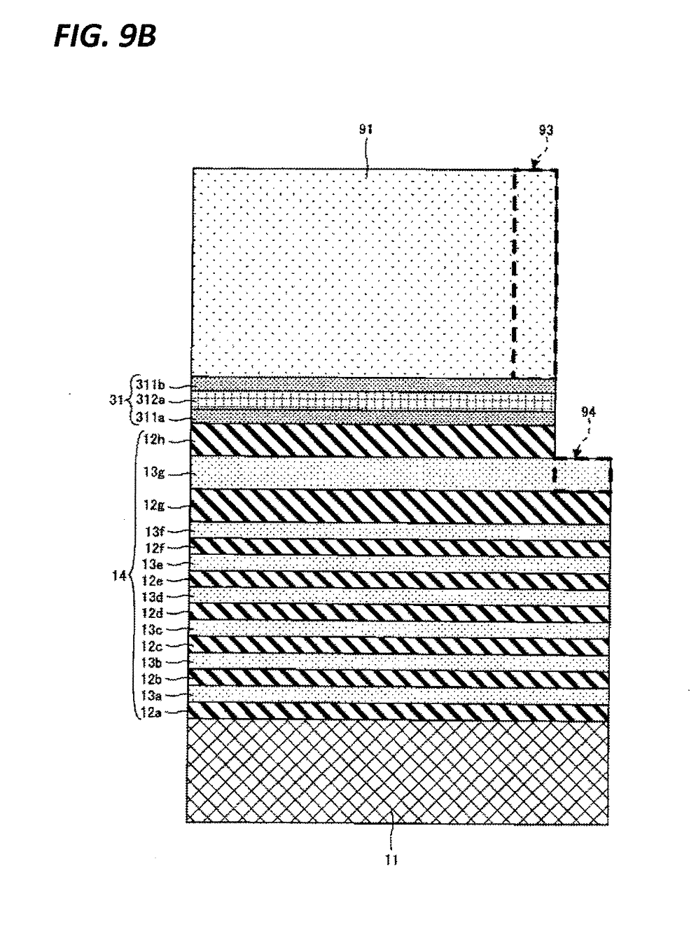

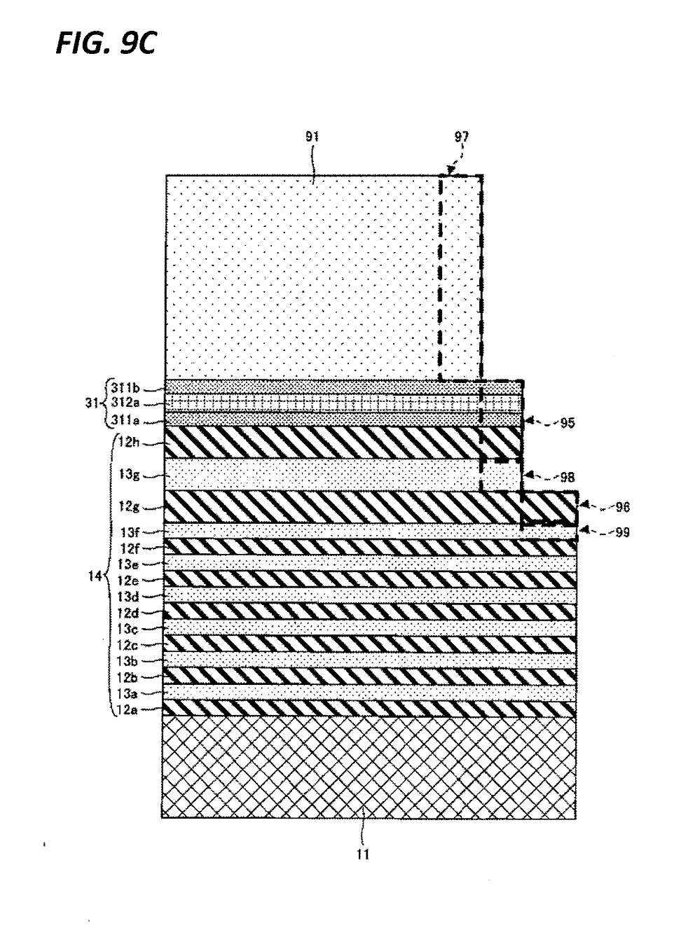

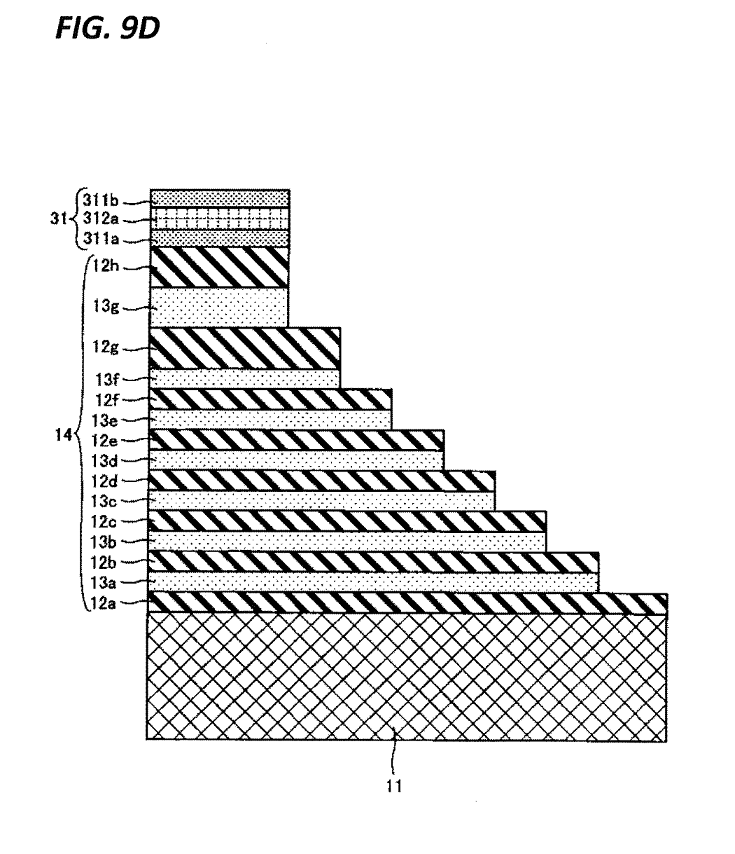

The respective processes will be described with reference to FIGS. 9A to 9D.

First, as illustrated in FIG. 9A, the mask disposing process is performed to dispose a mask 91 on the insulating film-carbon film laminate 14 through the hard mask film 31 (311a, 312a, and 311b). Here, the mask 91 is formed so that the hard mask film 31 disposed on the insulating film-carbon film laminate 14 is exposed by an extent to which the insulating film and the carbon film are etched in the subsequent etching process.

When the trimming process is repeatedly performed to remove a part of the mask 91 and the carbon film as described below, the thickness of the mask 91 is also gradually reduced. Thus, the mask 91 may be formed to a sufficient thickness in consideration of, for example, the number of times of repeating the trimming process.

A material for the mask 91 is not particularly limited. The mask 91 may be an organic mask formed of, for example, a photoresist. Also, as described below, the mask 91 may be formed of silicon nitride or amorphous silicon.

First, a case where, for example, a photoresist is used as the mask 91 will be described as an example.

In FIGS. 9A and 9D, only the word line contact region Y is illustrated. However, the mask may also be disposed on the entire surface on the insulating film-carbon film laminate 14 in the memory string region X. As such, the insulating film or the carbon film formed in the memory string region X may be suppressed from being removed in, for example, the etching process to be described below.

Then, the insulating film etching process is performed by anisotropic etching to remove an etching region 92 exposed from the mask 91 and surrounded by the dotted line in the drawing in the insulating film 12h of the uppermost layer of the insulating film-carbon film laminate 14. That is, the insulating film etching process may be performed to remove a part of the insulating film. Here, a portion of the hard mask film 31 included in the etching region 92 exposed from the mask 91 is also removed and thus, the state illustrated in FIG. 9B is obtained.

The trimming process is performed by isotropic etching in which a trimming region 93 of the mask 91, which is surrounded by the dotted line in the drawing, is removed so as to form a step as illustrated in FIG. 9B. When the mask is formed of a photoresist, a carbon film exposure region 94 where the carbon film 13g is exposed is also removed during the trimming process because the mask and the carbon film are formed of organic materials. That is, the trimming process may be performed to remove a part of the mask 91 and a part of the carbon film 13g. When the trimming process is performed, the state illustrated in FIG. 9C is obtained.

Then, the repetition process may be performed to alternately repeat the insulating film etching process and the trimming process.

For example, in the state illustrated in FIG. 9C, etching may be performed in the same manner as described in the above described etching process to remove etching regions 95 and 96. Then, the trimming process may be performed to remove a trimming region 97 in the mask 91 and carbon film exposure regions 98 and 99 of the carbon films which are exposed after etching processes.

By the repetition process, as illustrated in FIG. 9D, the end portion of the insulating film-carbon film laminate 14 may be processed in a stepwise form.

As described above, the mask 91 may be formed of silicon nitride or amorphous silicon. When the mask 91 is formed of silicon nitride or amorphous silicon, the insulating films and the carbon films may be removed in the etching process, and only the mask may be removed in the trimming process, unlike the case in which the mask 91 is formed of the photoresist as described above.

Specifically, in the process of FIG. 9A, the etching region 92 and the portion of the carbon film 12h just below the etching region 92 (a portion corresponding to the carbon film exposure region 94 in FIG. 9B) are removed by etching.

Then, the trimming process is performed to remove the trimming region 93 of the mask 91 in FIG. 9B.

Subsequently, the etching process is performed to remove etching regions 95 and 96, and trimming regions 97 and 98 in FIG. 9C by etching. Then, by repeating the trimming process and the etching process, the end portion of the insulating film-carbon film laminate 14 may be processed in a stepwise form as illustrated in FIG. 9D.

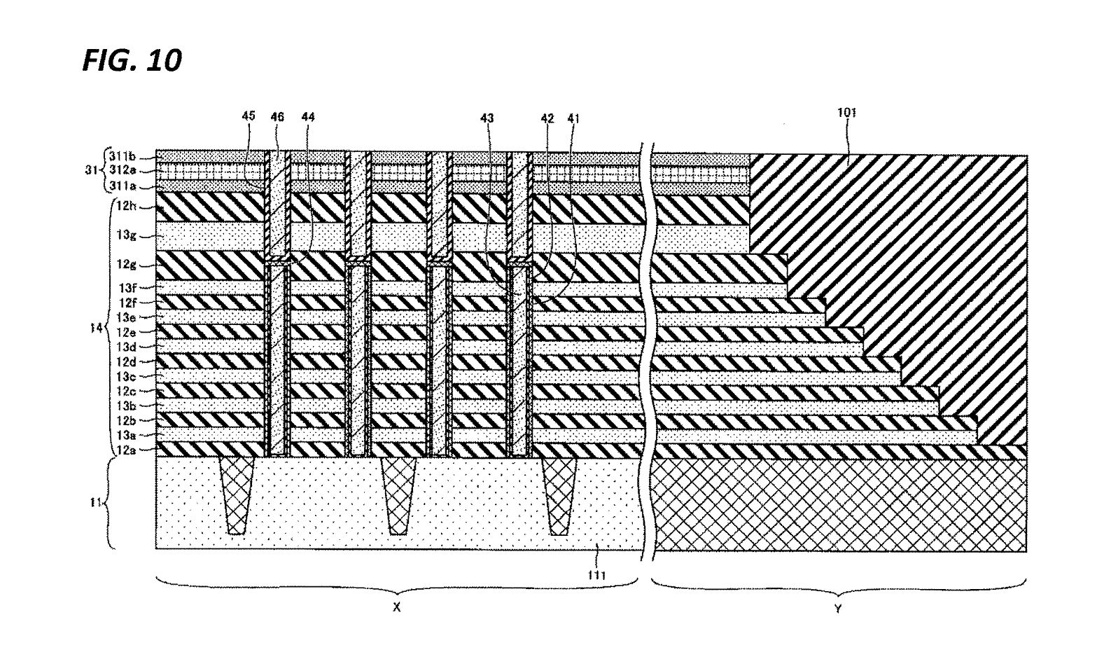

Then, the word line contact insulating film forming process may be performed to dispose an insulating film 101 on the end portion of the insulating film-carbon film laminate 14, which has been processed in the stepwise form. The exemplary configuration of the semiconductor device after the insulating film 101 is formed is illustrated in FIG. 10.

A material for the insulating film 101 is not particularly limited, but may be, for example, a silicon oxide film as in the insulating film 81 formed on the word line contacts in the word line contact insulating film forming process of the first exemplary embodiment. The insulating film 101 may be formed by, for example, a CVD method, an ALD method or a MLD method. Especially, the insulating film 101 is preferably the CVD method.

The insulating film 101 may be formed on the entire top side of the insulating film-carbon film laminate 14 as well as on the end portion processed in the stepwise form. In this case, the insulating film formed on the insulating film-carbon film laminate 14 may be removed by, for example, CMP. Accordingly, as illustrated in FIG. 10, the hard mask film 31 on the insulating film-carbon film laminate 14 may be exposed so that the hard mask film 31 and the top surface of the insulating film 101 may be positioned on the same plane.

(Electrode Forming Process and Process of Forming Insulating Films Between Memory Strings)

After the above-described processes, the electrode forming process described in the first exemplary embodiment may be performed.

The electrode forming process may include the following processes.

A carbon film removing process for removing the carbon films 13a to 13g included in the insulating film-carbon film laminate 14.

An electrode film forming process for forming electrode films in regions remaining after the carbon films are removed in the carbon film removing process to obtain an insulating film-electrode film laminate in which the insulating films and the electrode films are laminated in a plurality of layers.

The carbon film removing process may be performed using a dry removal means (a sacrificial film removal means) as described in the first exemplary embodiment. Here, openings may be preferably formed in the insulating film-carbon film laminate so as to supply the dry removal means, for example, oxygen plasma to the carbon films.

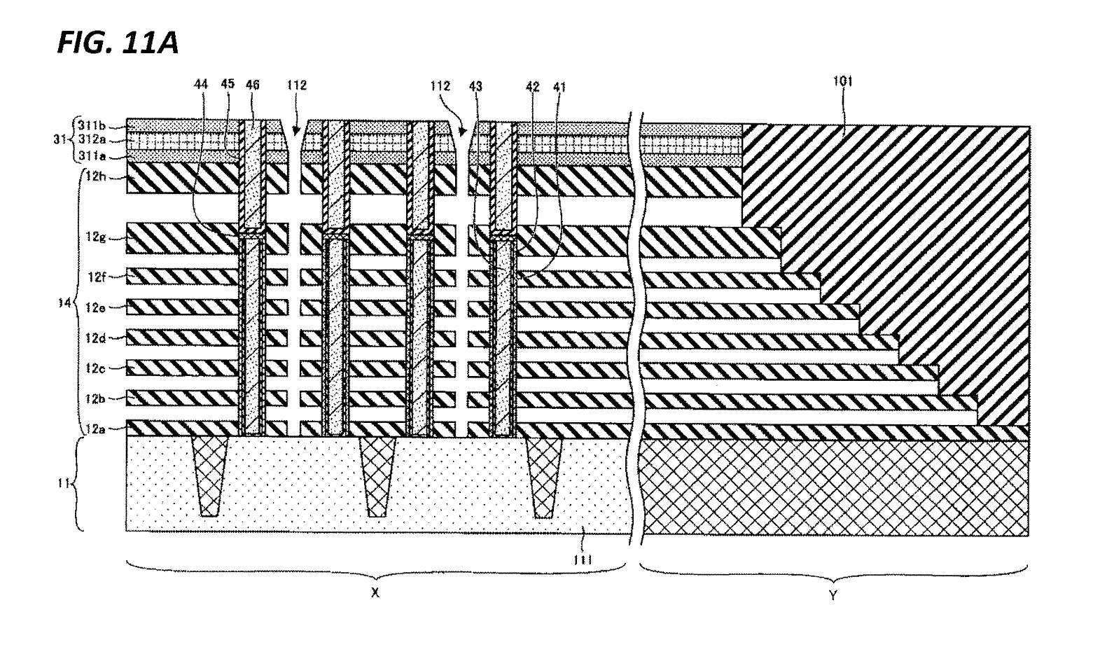

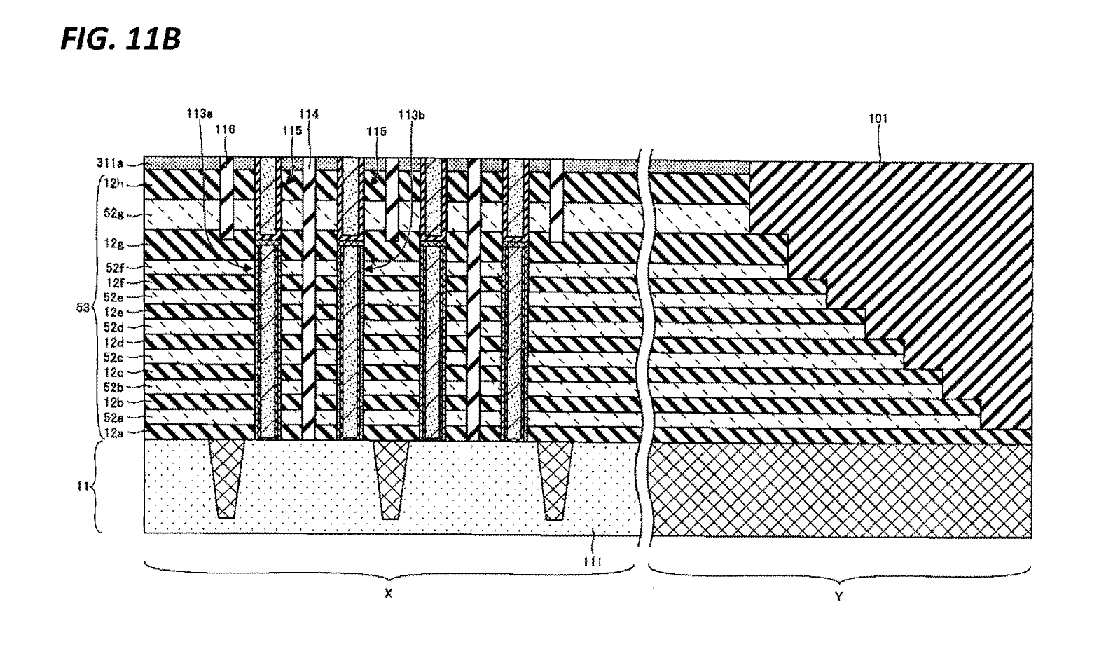

Accordingly, first, openings 112 to be formed with the insulating films for insulating the memory strings from each other may be formed, as illustrated in FIG. 11A. The openings 112 may be formed by etching after a mask layer is formed, as in, for example, the openings 51 in the first exemplary embodiment. This process has already been described in the first exemplary embodiment, and thus, detailed descriptions thereof will be omitted.

Then, the carbon film removing process may be performed to remove the carbon films 13a to 13g included in the insulating film-carbon film laminate 14.

As described in the first exemplary embodiment, when the silicon film forming process is performed before and after the carbon film forming process, the formed silicon film may have a composition of a silicon oxide film or a composition close to the silicon oxide film when the carbon film removing process is performed. Thus, in the carbon film removing process, the silicon film may be oxidized.

While an ashing processing using the oxygen plasma is performed in the carbon film removing process, silicon films may be oxidized. Separately from the carbon film removing process, a silicon film oxidizing process may be provided to oxidize the silicon films.

When some residue of the carbon film is produced in the carbon film removing process, wet washing using a solution having a weak surface tension may be used in combination. In this case, the wet washing may be performed in a short time by using the solution having the weak surface tension. Thus, the insulating films may be suppressed from being deflected.

When the carbon film removing process is performed, the carbon films between the insulating films 12a to 12h are removed to leave cavities as illustrated in FIG. 11A.

After the carbon film removing process, an electrode film forming process may be performed, in which electrode films are formed in the regions from which the carbon films have been removed in the carbon film removing process so as to form an insulating film-electrode film laminate in which the insulating films and the electrode films are laminated in a plurality of layers.

As described in the first exemplary embodiment, before the electrode films are formed, a titanium nitride film as a barrier film may be formed on the surface of each of the insulating films 12a to 12h.

The details of the carbon film removing process and the electrode film forming process may be the same as those in the first exemplary embodiment, and thus descriptions thereof will be omitted.

The electrode films are formed by the electrode film forming process, as in FIG. 5C described in the first exemplary embodiment, a material constituting the electrode films is also disposed on the top of the hard mask film 31, and within the openings 112 to be formed with the insulating films for insulating the memory strings from each other. Also, in the present exemplary embodiment, the electrode material is also disposed on the top of the insulating film 101.

Thus, the electrode material disposed on the top of the hard mask film 31 and the insulating film 101 or within the openings 112 to be formed with the insulating films for insulating the memory strings from each other may be removed in the same manner as in the first exemplary embodiment.

The electrode material on the hard mask film 31 or the insulating film 101 may be removed by, for example, CMP. Here, a part of the hard mask film 31 and a part of the insulating film 101 may also be removed. However, for example, the first inorganic material layer 311a may be left to be used as a mask when openings to be provided with insulating films for insulating the selection gates from each other are formed as described below.

The electrode material disposed within the openings 112 to be formed with the insulating films for insulating the memory strings from each other may be removed by etching as in the electrode material disposed within the openings 51 as described in the first exemplary embodiment. That is, for example, a mask layer including an organic mask film, an SOG film, and a photoresist provided with openings corresponding to the openings 112 may be disposed on the top surface of the hard mask film 31 (311a) to perform etching.

Then, the insulating film forming process may be performed as in the first exemplary embodiment to form insulating films between the memory strings.

First, in connection with the selection gates, each of the insulating films may be formed between every two selection gates. Thus, an opening to be formed with an insulating film for insulating the selection gates from each other may be formed between the memory strings not formed with the opening 112 in the area where the selection gates are opposite to each other. The sequence for forming the openings is the same as that for forming the openings 112 to be formed with the insulating films for insulating the memory strings from each other, and thus, description thereof will be omitted.

Then, in the same manner as in the first exemplary embodiment, insulating films may be disposed in the openings 112 to be formed with the insulating films for insulating the memory strings from each other, and in the openings to be formed with the insulation films for insulating the selection gates from each other.

Accordingly, as illustrated in FIG. 11B, the insulating films 114 are disposed between memory strings 113a and 113b connected via the source region 111 formed on the substrate 11, and the insulating films 114 and 116 are alternately disposed between the selection gates 115.

After this process, the top surfaces of the selection gates 115 are exposed. Thus, as described in the memory string forming process of the first exemplary embodiment, the drain region forming process may be performed so that, for example, arsenic is doped on the top surfaces of the selection gates 115 to form drain regions.

Processes for forming various members required for the semiconductor device may be further performed. For example, as described in the first exemplary embodiment, a bit line forming process for forming bit lines on the respective memory strings may be performed, and a word line wiring forming process for forming wirings for word lines may be performed on the word line contacts formed in the stepwise form.

In the method of manufacturing the semiconductor device of the present exemplary embodiment, after the insulating film-carbon film laminate is formed, the carbon films serving as the sacrificial films may be removed by a dry removal means. Thus, the insulating films may be suppressed from being deflected and thus, the yield may be improved.

In the present exemplary embodiment, the configuration of the NAND-type flash memory having a three-dimensional structure has been described as an example, but the present disclosure is not limited thereto. For example, the semiconductor device may be a ReRAM.

### Third Exemplary Embodiment

In the first and second exemplary embodiments, a case where the insulating film-carbon film laminate is formed has been described as an example, but the present disclosure is not limited thereto. In the method of manufacturing the semiconductor device, a laminate of carbon films and electrode films may be formed, instead of insulating films.

Specifically, for example, the following processes may be provided.

An electrode film forming process for forming an electrode film on one side of a substrate.

A carbon film forming process for forming a carbon film on the electrode film formed in the electrode film forming process.

An electrode film-carbon film laminate forming process for forming an electrode film-carbon film laminate by repeating the electrode film forming process and the carbon film forming process multiple times, in which electrode films and carbon films are alternately laminated in a plurality of layers on one side of the substrate.

A carbon film removing process for removing the carbon films included in the electrode film-carbon film laminate.

Hereinafter, each of the electrode film forming process, the carbon film forming process, and the electrode film-carbon film laminate forming process will be described.

Since a substrate 11 which is the same as that described in the first exemplary embodiment may be used, descriptions thereof will be omitted herein.

On the substrate 11, an insulating film 121a may be formed. Thus, an insulating film forming process may be performed before performing the electrode film forming process for forming an electrode film 122a.

The insulating film 121a may be formed in the same manner as the insulating film 11a as described in the first exemplary embodiment, and thus descriptions thereof will be omitted herein.

The carbon film forming process may be performed prior to the electrode film forming process, without performing the insulating film forming process. Then, after a carbon film is removed as described below, the insulating film 121a may be formed by disposing an insulating film in a cavity formed by removing the carbon film.

In the electrode film forming process, the electrode film 122a is formed on one side of the substrate 11. The electrode film formed in the electrode film forming process is not particularly limited, but may be, for example, a tungsten-containing film. Specifically, for example, tungsten or tungsten nitride may be used. The electrode film may be formed by, for example, a CVD method.

Then, the carbon film forming process will be described.

In the carbon film forming process, a carbon film 123a, for example, an amorphous carbon film, may be formed on the electrode film 122a formed in the electrode film forming process.

The carbon film 123a may be formed in the same manner as the carbon film as described in the first exemplary embodiment, and thus descriptions thereof will be omitted herein.

Film formation conditions for the carbon film forming process are not particularly limited. The film formation temperature of the carbon film may range from 500° C. to 900° C. In particular, the film formation temperature may range from 600° C. to 800° C.

The silicon film forming process may be further performed before the carbon film forming process is performed and after the carbon film forming process is performed. That is, the silicon film forming process for forming a silicon film (a seed layer) may be performed after the electrode film forming process before the carbon film forming process, and subsequently to the carbon film forming process. For example, when the silicon film forming process is performed the adhesion between the electrode film and the carbon film may be improved in the case where the adhesion between the electrode film and the carbon film is low.

The silicon film forming process may be performed in the same manner as that in the first exemplary embodiment, and thus descriptions thereof will be omitted herein.

Hereinafter, the electrode film-carbon film laminate forming process will be described.

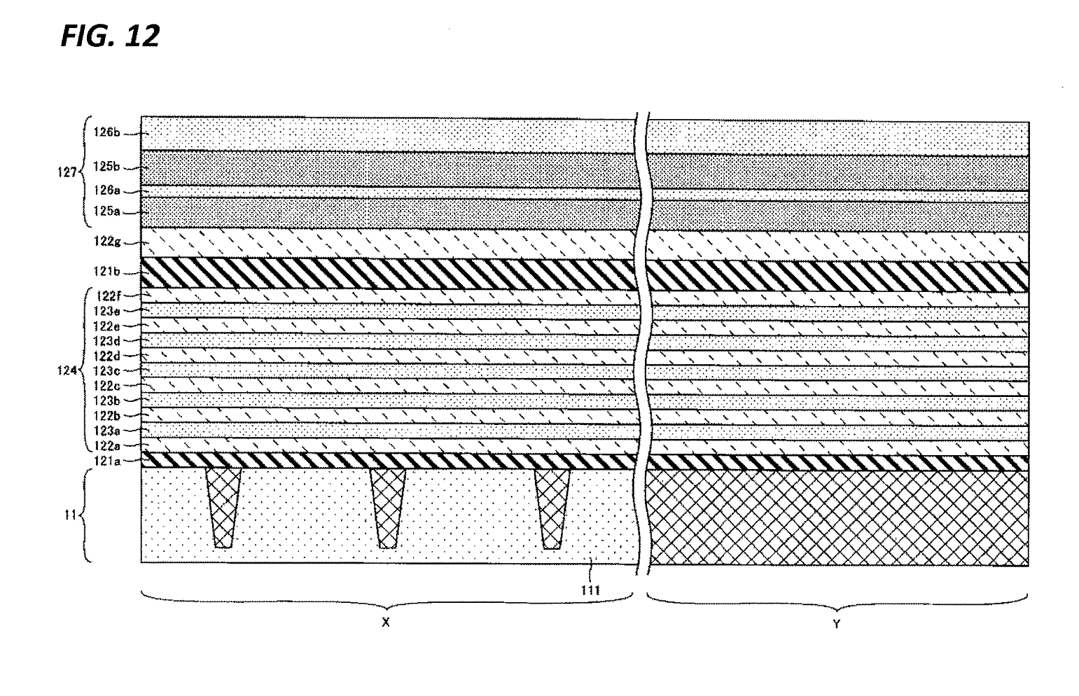

In the electrode film-carbon film laminate forming process, the electrode film forming process and the carbon film forming process may be alternately repeatedly performed. Accordingly, the electrode films 122b to 122f and the carbon films 123b to 123e may be laminated on one side of the substrate 11 to form an electrode film-carbon film laminate 124 as illustrated in FIG. 12. The electrode film forming process and the carbon film forming process in the electrode film-carbon film laminate forming process may be performed in the sequence described above, and thus descriptions thereof will be omitted herein.

There is no limitation in the number of times of repeating the electrode film forming process and the carbon film forming process, but the electrode film forming process and the carbon film forming process may be repeated according to the required number of layers. Meanwhile, when the semiconductor device is formed by the electrode film-carbon film laminate, the carbon films serve as sacrificial films to be removed. Thus, the electrode film-carbon film laminate forming process may be performed so that the uppermost layer becomes the electrode film. In the example of FIG. 12, five (5) layers of carbon films and six (6) layers of electrode films are laminated, but the number of layers of respective films in the electrode film-carbon film laminate is not particularly limited. A plurality of layers may be further laminated. Also, the number of layers may be less than that in the case of FIG. 12.

As illustrated in FIG. 12, an insulating film 121b and an electrode film 122g may be further formed on the electrode film-carbon film laminate 124. That is, the insulating film forming process and the electrode film forming process may be further performed. The electrode film 122g formed herein may be used as, for example, electrodes of selection gates. Here, in the portion of the insulating film 121b, a carbon film may be formed, and then may be replaced with an insulating film in the process to be described below.

(Trench Forming Process)

On the electrode film-carbon film laminate obtained by the semiconductor device manufacturing method described so far, a trench forming process including the following processes may be further performed to form trenches in which, for example, memory strings are to be formed.

A hard mask film forming process for forming a plurality of hard mask films on the electrode film-carbon film laminate.

An electrode film and carbon film etching process for etching the electrode films and the carbon films using the hard mask films as a mask.

First, the hard mask film forming process will be described.

In the hard mask film forming process, a mask used for performing the electrode film and carbon film etching process to be described later is disposed. As illustrated in FIG. 12, a hard mask film 127 may be disposed on the top surface of the electrode film-carbon film laminate 124. As described above, when the insulating film 121b and the electrode film 122g are disposed on the top surface of the electrode film-carbon film laminate 124, the hard mask film 127 is disposed through the insulating film 121b and the electrode film 122g.

The hard mask film only has to be configured to serve as a mask in the electrode film and carbon film etching process to be described later, and the configuration of the hard mask film is not particularly limited. The hard mask film 127 may include first inorganic material layers 125a and 125b, and second inorganic material layers 126a and 126b made of a material different from the material for the first inorganic material layers. In this manner, the hard mask film 127 may include the layers made of different materials, and thus the layers made of different materials may serve as a stopper layer when, for example, CMP is performed.

As in the first exemplary embodiment, the hard mask film 127 may include the plurality of first inorganic material layers 125a and 125b and the plurality of second inorganic material layers 126a and 126b which are alternately formed. The hard mask film may include a third inorganic material layer.

The materials for the first inorganic material layer 125a and 125b, and the second inorganic material layer 126a and 126b included in the hard mask film 127 are not particularly limited. For example, polysilicon, silicon oxide, or silicon nitride may be used.

A mask layer (not illustrated) used for etching may be further disposed on the hard mask film 127. The configuration of the mask layer is not particularly limited. For example, as described and illustrated in the first exemplary embodiment, an organic mask film, a SOG film, and a photoresist may be disposed in this order from the hard mask film side. In this case, a desired pattern is formed on the photoresist and etching is performed so that the pattern formed on the photoresist is firstly transferred to the SOG film and the organic mask film below the photoresist. Then, etching is further performed so that the pattern is transferred to the hard mask film, and then the electrode films and the carbon films of the electrode film-carbon film laminate 124 disposed below the hard mask film, and insulating films may be etched. During the etching process, the organic mask film, the SOG film, and the photoresist are removed. Then, trenches for forming memory strings therein are formed in the electrode films 122a to 122g, the carbon films 123a to 123e, and the insulating films 121a and 121b as well.

Conditions for performing etching are not particularly limited as long as the electrode films 122a to 122g and the carbon films 123a to 123e may be etched. In a case where the insulating films 121a and 121b are formed, the etching may be performed under the conditions allowing the insulating films 121a and 121b to be etched.

Specifically, for example, plasma etching may be performed.

A gas used for performing the plasma etching is not particularly limited. For example, when a gas obtained by adding Ar and O₂ to SF₆ or NF₃ is used, the electrode films and the carbon films may be simultaneously etched.

A gas capable of etching the electrode films and a gas capable of etching the carbon films may be alternately supplied to perform plasma etching. For example, when the electrode films are etched, a gas including any one of SF₆, NF₃, Cl₂, and HBr may be used. When the carbon films are etched, a mixed gas of O₂ and carbonyl sulfide (COS), or a mixed gas of O₂, N₂, and H₂ may be used.

When the insulating films are subjected to plasma etching, for example, a gas obtained by adding Ar and O₂ to CF₄F₈ or C₄F₆ may be used.

Conditions for performing plasma etching are not particularly limited. For example, the plasma etching may be performed at a gas pressure ranging from 10 mTorr to 50 mTorr, with a power output ranging from 500 W to 2000 W, and a bias output ranging from 1000 W to 4000 W.

The shape of each of the trenches may correspond to a memory string to be described later, or may employ, for example, a cylindrical shape. The bottom surface of each of the trenches may be preferably formed so that the substrate 11 is exposed. As in the first and second exemplary embodiments, the trenches may be arranged at a plurality of locations in the memory string region X in FIG. 12 in a direction parallel to the paper sheet or in a direction perpendicular to the paper sheet.

(Memory String Forming Process)

In the method of manufacturing the semiconductor device of the present exemplary embodiment, a memory string forming process may be performed to sequentially form members constituting the memory strings within the formed trenches.

In the memory string forming process, for example, following processes may be performed.

An IGD film and charge trap film forming process for forming an IGD film and a charge trap film on the surface of each of the trenches.

An IGD film and charge trap film removing process for removing the IGD film and the charge trap film formed on the bottom surface of each of the trenches.

A tunnel oxide film forming process for forming a tunnel oxide film on the surface of the IGD film and the charge trap film.

A channel forming process for forming channel portions of memory strings within the trenches.

A process of removing a part of the hard mask film.

A process of forming selection gates.

The respective processes may be performed in the same manner as those of the memory string forming process as described in the first exemplary embodiment, and thus descriptions thereof will be omitted.

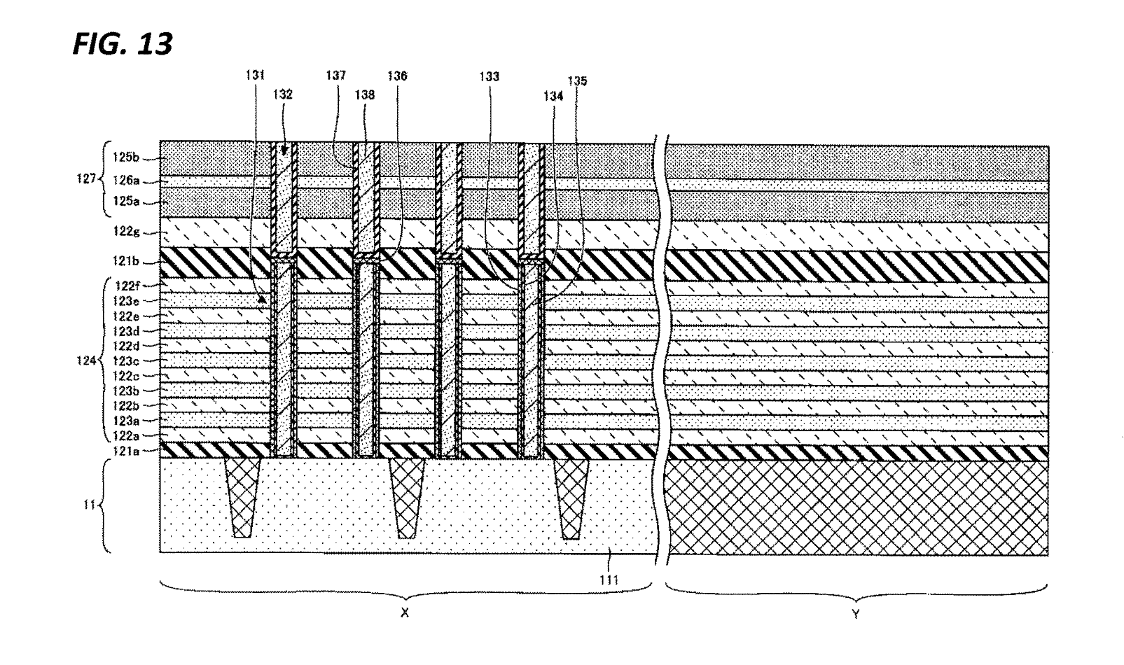

After the memory string forming process is performed, for example, as illustrated in FIG. 13, memory strings 131 formed with selection gates 132 thereon may be formed within the formed trenches. In a lower portion of each of the memory strings 131, as in the first exemplary embodiment, an IGD film-charge trap film laminate 133 and a tunnel oxide film 134 are laminated in this order from the surface of each of the trenches. Channel portions 135 may be filled with, for example, polysilicon.

The portion of each of the selection gates 132 may include a source region 136, an oxide insulating film 137, and a selection gate channel 138.

(Insulating Film Forming Process Between Memory Strings)

In the method of manufacturing the semiconductor device of the present exemplary embodiment, an insulating film forming process for forming insulating films between memory strings may be performed so as to insulate memory strings from each other and to insulate selection gates from each other.

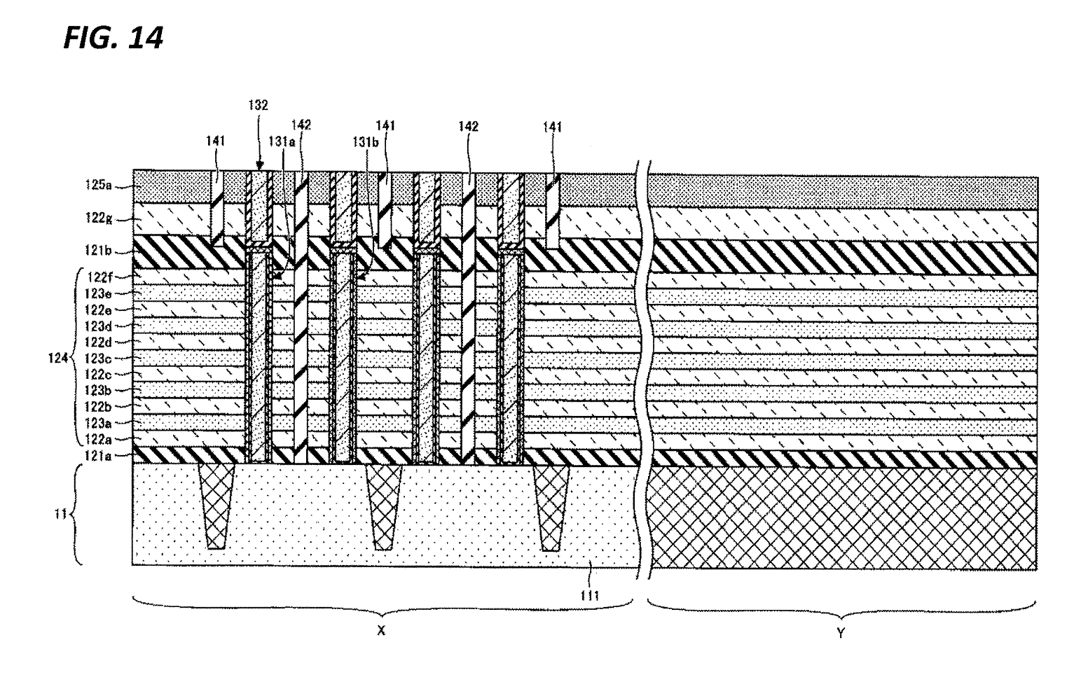

As illustrated in FIG. 14, insulating films 142 may be disposed between memory strings 131a and 131b connected via the source region 111 formed on the substrate 11.

A method of forming the insulating films 142 will be described.

For example, an opening (between memory strings) forming process may be performed so as to form openings to be formed with the insulating films 142 for insulating the memory strings from each other, as in the openings 51 in the first exemplary embodiment. The openings may be formed as in the first exemplary embodiment. That is, an organic mask film, an SOG film and a photoresist provided with openings corresponding to the openings for the insulating films 142 may be disposed on the hard mask film 127 in FIG. 13, and etching may be performed to form the openings. The organic mask film, the SOG film and the photoresist are lost during the etching process.

Then, the insulating film forming process for forming insulating films (between memory strings) is performed to dispose the insulating films 142 within the openings. The insulating films 142 may be formed by, for example, a CVD method. When the insulating films 142 are formed, the insulating films 142 are formed on the top of the hard mask film 127 as well as within the openings Thus, the insulating film on the top of the hard mask film 127 may be removed together with the first inorganic material layer 125b of the uppermost layer in the hard mask film 127 by, for example, CMP.

Although the insulating films 142 between the memory strings also serve as insulating films between the selection gates 132, an insulating film may be disposed between every two selection gates 132. Thus, the insulating films 141 may be further formed between the selection gates 132 which are not formed with the insulating films 142. The insulating films 141 only have to insulate the selection gates 132. Thus, the openings may be formed to a depth corresponding to the depth of the selection gates 132, and the insulating films 141 may be disposed in the openings. The method of forming the openings, and the method of forming the insulating films in the openings may be performed in the same manner as in the insulating films 142, and thus descriptions thereof will be omitted herein.

When the insulating films 141 are formed, the insulating film is also formed on the hard mask film as in the insulating films 142, and thus may be removed together with the second inorganic material layer 126a (see FIG. 13) of the uppermost layer in the hard mask film 127 by, for example, CMP.

In this example, after the insulating films 142 are formed, openings to be formed with the insulating films 141 are formed, and then the insulating films 141 are formed, but the present disclosure is not limited thereto. For example, as in the first exemplary embodiment, after the openings for forming the insulating films 142 therein, and the openings for forming the insulating films 141 therein are formed, the insulating films 141 and the insulating films 142 may be simultaneously formed.

(Word Line Contact Forming Process)

In the method of manufacturing the semiconductor device of the present exemplary embodiment, the electrode films and the carbon films may be etched in a stepwise form in order to provide word line contacts in the word line contact region Y. The word line contact forming process may include the following processes.

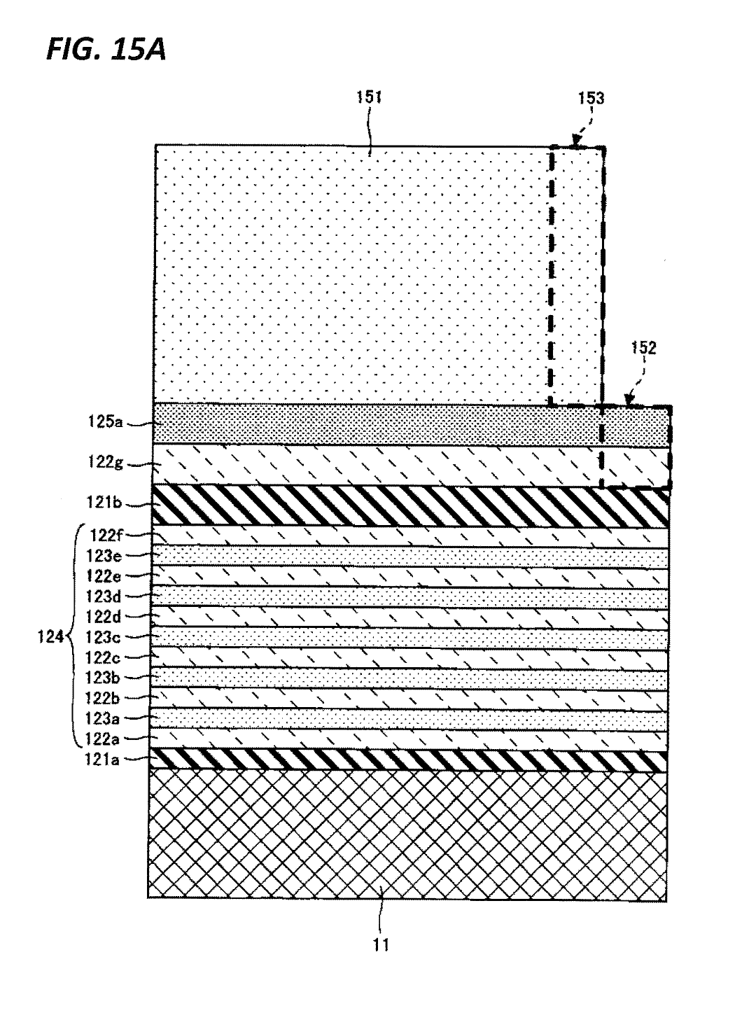

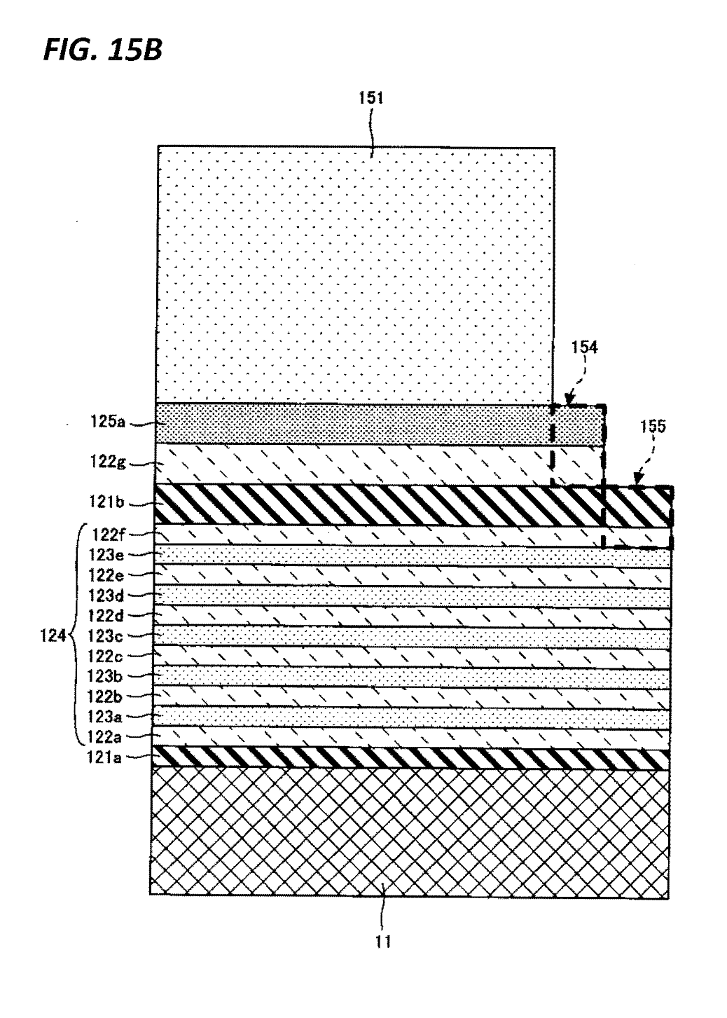

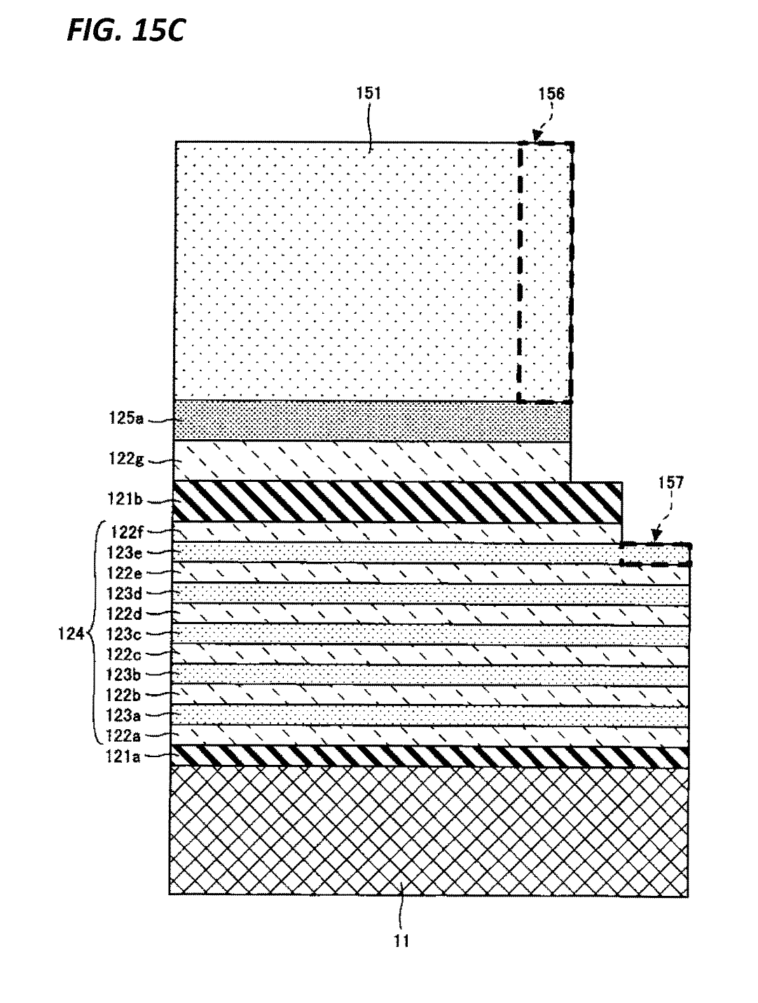

As illustrated in FIG. 15A, a mask disposing process is performed to dispose a mask 151 on the electrode film-carbon film laminate 124 through the hard mask film 125a. Here, the mask 151 is formed so that the hard mask film 125a is exposed by an extent to which the hard mask film 125a and the electrode film 122g are etched in the subsequent etching process.

When a trimming process for removing a part of the mask 151 is repeatedly performed as described below, the thickness of the mask 151 is also gradually reduced. Thus, the mask 151 is preferably formed to a sufficient thickness in consideration of, for example, the number of times of repeating the trimming process. Also, the mask 151 may be an organic mask formed of, for example, a photoresist so that the mask 151 may be removed in the trimming process.

FIGS. 15A to 15C illustrates only the word line contact region Y. However, the mask may also be disposed on the entire surface on the electrode film-carbon film laminate 124 in the memory string region X so that the electrode film or the carbon film formed in the memory string region X is suppressed from being etched in, for example, the etching process to be described below.

Then, an electrode film etching process is performed by anisotropic etching to remove an etching region 152 exposed from the mask and surrounded by the dotted line in FIG. 15A in the electrode film 122g. Here, the hard mask film 125a within the etching region 152 is also removed.

A trimming process is performed by isotropic etching in which a trimming region 153 of the mask 151 is removed so as to form a step. The trimming region 153 is surrounded by dotted line in FIG. 15A. Accordingly, the state illustrated in FIG. 15B is obtained.

Then, in FIG. 15B, an electrode film etching process is performed by anisotropic etching to remove etching regions 154 and 155 surrounded by dotted line. Here, the electrode films 122g and 122f included in the etching regions 154 and 155 are removed. Also, the hard mask film 125a, and the insulating film 121b included in the etching regions 154 and 155 are also removed. Accordingly, the state illustrated in FIG. 15C is obtained.

Then, in FIG. 15C, a trimming process is performed to trim a trimming region 156 of the mask 151 and an trimming region 157 of the exposed carbon film 123e, in which the trimming regions 156 and 157 are surrounded by dotted line.

Then, a repetition process of alternately repeating the electrode film etching process and the trimming process may be performed.

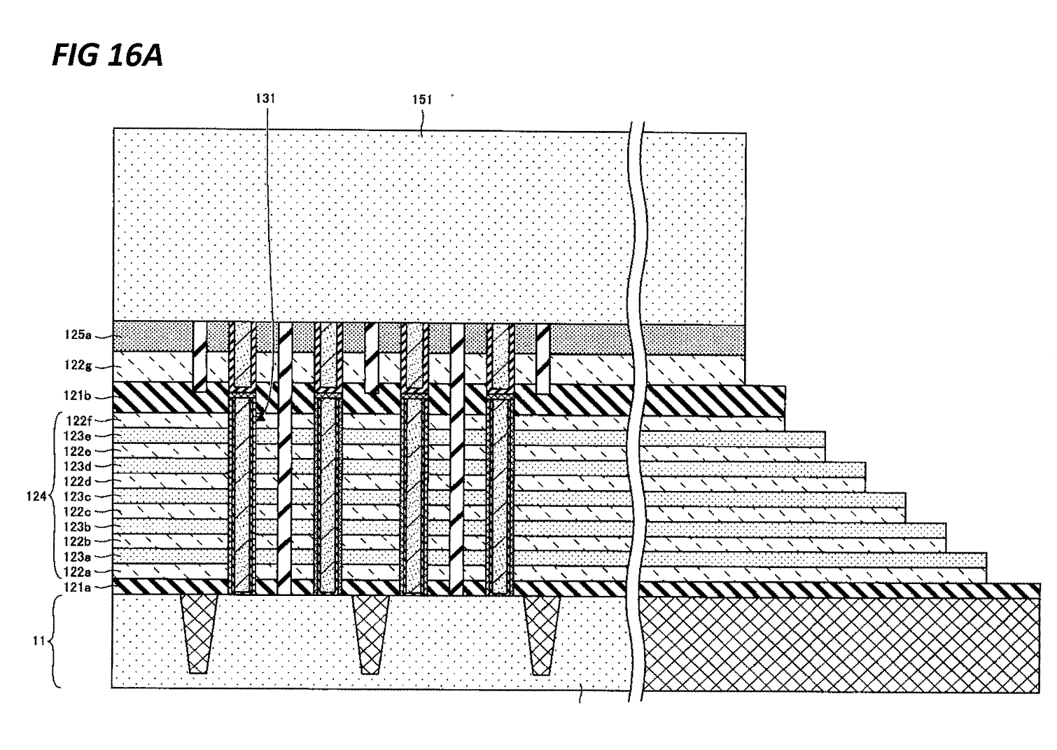

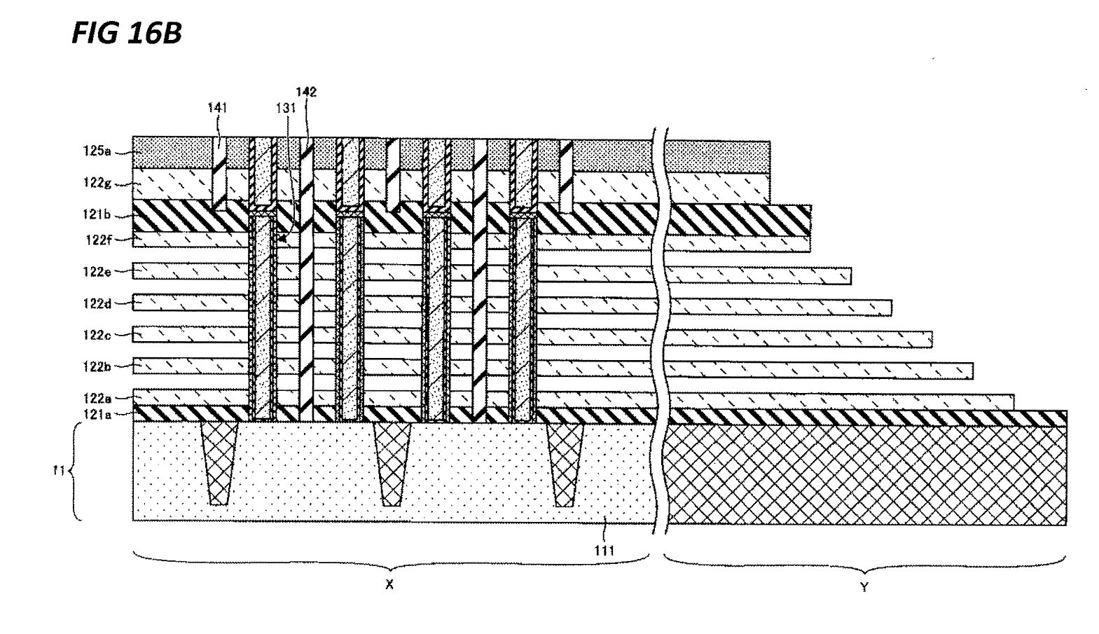

By the repetition process, as illustrated in FIG. 16A, the end portion of the electrode film-carbon film laminate 124 may be processed in a stepwise form.

(Carbon Film Removing Process and Insulating Film Forming Process)

In the method of manufacturing the semiconductor device of the present exemplary embodiment, the carbon films 123a to 123e serving as sacrificial films may be removed to form (interlayer) insulating films. In this case, the method of manufacturing the semiconductor device of the present exemplary embodiment may include a carbon film removing process, in which the carbon films 123a to 123e included in the electrode film-carbon film laminate 124 as described above are removed.

Descriptions will be made with reference to FIGS. 16A and 16B.

For example, as illustrated in FIG. 16A, the electrode film-carbon film laminate 124 has a configuration in which the carbon films 123a to 123e are disposed between the electrode films 122a to 122f.

When the carbon film removing process is performed on the electrode film-carbon film laminate 124 illustrated in FIG. 16A, the carbon films disposed between the electrode films may be removed to leave cavities as illustrated in FIG. 16B. Since the electrode films 122a to 122f are supported by the memory strings 131, the cavities between the electrode films are maintained.

When the mask 151 used in the word line contact forming process is an organic mask, as illustrated in FIG. 16B, the mask 151 may be removed together with the carbon films 123a to 123e in the carbon film removing process.

A specific method of the carbon film removing process is not particularly limited. For example, the carbon film removing process may be performed by an ashing processing using oxygen plasma.

When some residue of the carbon film is produced in the carbon film removing process, wet washing using a solution having a weak surface tension may be used in combination. In this case, the wet washing may be performed in a short time by using the solution having the weak surface tension. Thus, the electrode films may be suppressed from being deflected.

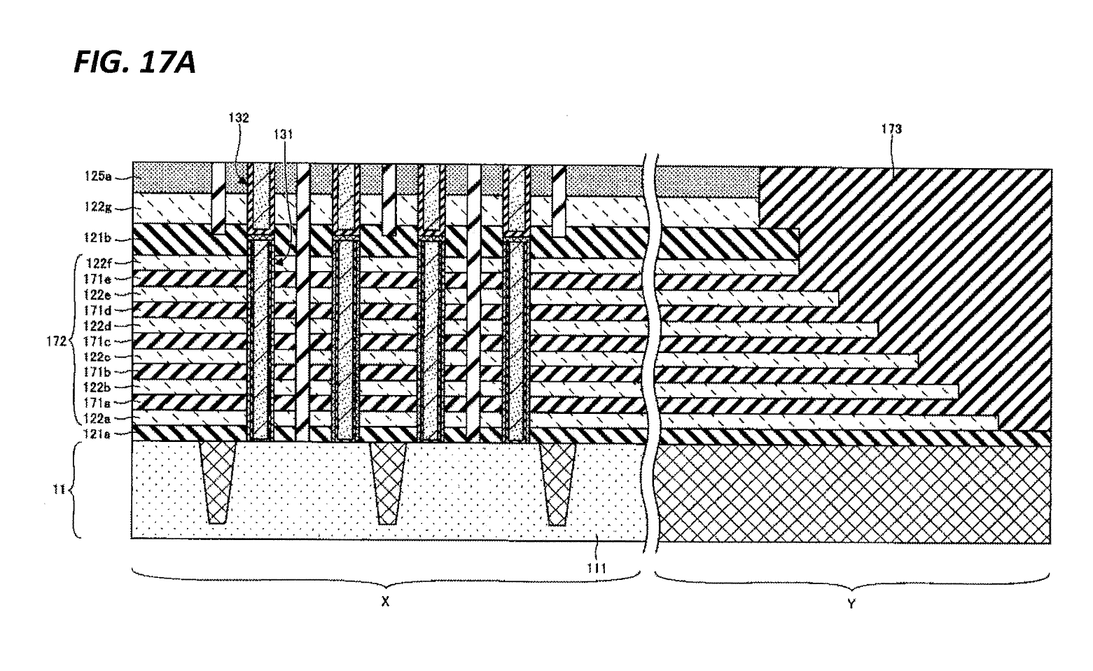

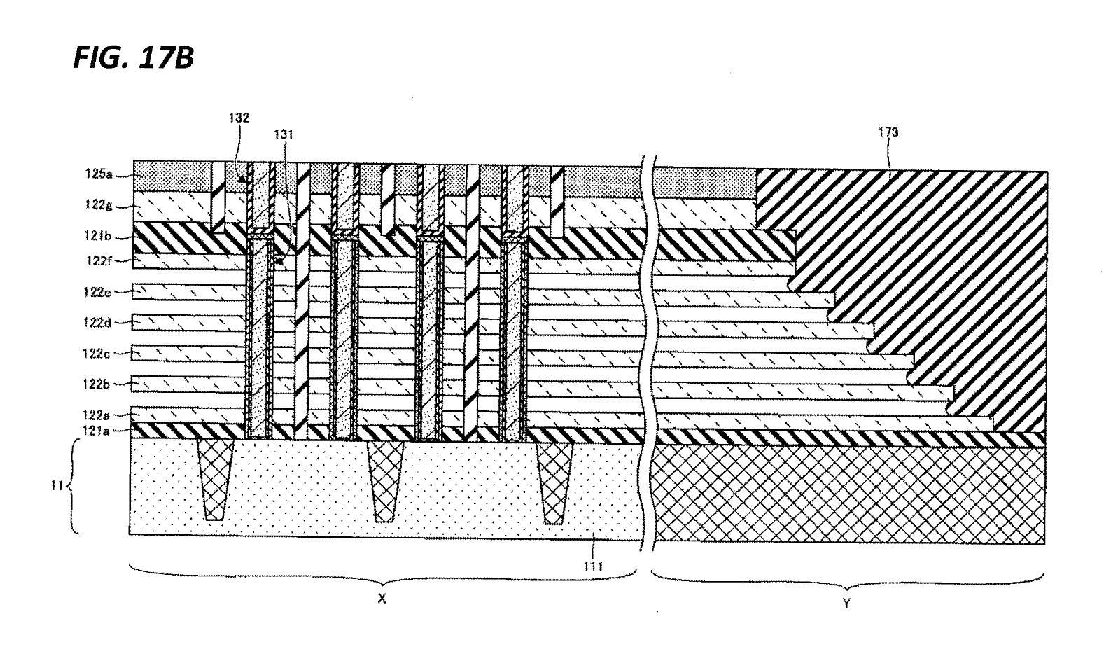

Then, as illustrated in FIG. 17A, an insulating film forming process may be further performed in which (interlayer) insulating films 171a to 171e are disposed in the regions from which the carbon films 123a to 123e are removed by the carbon film removing process, that is, in the cavities formed between the electrode films 122a to 122f. Accordingly, an electrode film-insulating film laminate 172 may be formed in which the insulating films 171a to 171e and the electrode films 122a to 122f are alternately laminated.

Here, as illustrated in FIG. 17A, a (word line contact) insulating film 173 may be disposed on word line contacts, that is, the end portion of the electrode films 122a to 122f, which has been processed in the stepwise form.

In the example in FIG. 17A, the (interlayer) insulating films 171a to 171e are disposed between the electrode films 122a to 122f. However, as illustrated in FIG. 17B, the insulating films may not be disposed between the electrode films 122a to 122f. That is, the regions between the electrode films 122a to 122f, from which the carbon films 123a to 123e are removed in the carbon film removing process, may be air gaps. Even in a case where the insulating films are not disposed, when the obtained semiconductor device is placed under a vacuum or predetermined atmosphere, the same effect as that of the insulating films may be exhibited due to the cavities formed between the electrode films 122a to 122f. Also, in this case as well, the (word line contact) insulating film 173 may be disposed on word line contacts, that is, the end portion of the electrode films 122a to 122f, which has been processed in the stepwise form, as illustrated in FIG. 17B.

A material for the (interlayer) insulating films 171a to 171e or the (word line contact) insulating film 173 is not particularly limited, but may be, for example, a silicon oxide film. Before the (interlayer) insulating films 171a to 171e and/or the (word line contact) insulating film 173 are formed, a titanium nitride film or a silicon nitride film may be formed on the surfaces of the electrode films 122a to 122f as antioxidant films of the electrode films 122a to 122f. A method of forming the titanium nitride film or the silicon nitride film is not particularly limited. For example, a CVD method, an ALD method, or a MLD method may be used for film formation. Especially, the ALD may be preferably used.

Conditions for forming the (interlayer) insulating films 171a to 171e or the (word line contact) insulating film 173 are not particularly limited. For example, the same conditions as those in the insulating films 12a to 12h formed in the first exemplary embodiment may be used for film formation.

In the semiconductor device illustrated in FIGS. 17A and 17B, the top surfaces of the selection gates 132 are exposed. Thus, as described in the memory string forming process of the first exemplary embodiment, the drain region forming process may be performed so that, for example, arsenic is doped on the top surfaces of the selection gate channels to form drain regions.

Processes for forming various members required for the semiconductor device may be further performed. For example, as described in the first exemplary embodiment, a process of forming bit lines on the respective memory strings 131 may be performed, and a process of forming wiring for word lines may be performed on the word line contact formed in the stepwise form.

As described above, the method of manufacturing the semiconductor device of the present exemplary embodiment has been described. In the semiconductor device manufacturing method, after the electrode film-carbon film laminate is formed, carbon films serving as sacrificial films may be removed by a dry removal means. Accordingly, the electrode films are suppressed from being deflected, and the yield may be improved.

In the present exemplary embodiment, the configuration of the NAND-type flash memory having a three-dimensional structure has been described as an example, but the present disclosure is not limited thereto. For example, the semiconductor device may be a ReRAM.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of manufacturing a semiconductor device, the method comprising:
forming an insulating film on one side of a substrate;
forming a carbon film on the insulating film formed in the forming of the insulating film;
forming an insulating film-carbon film laminate including a plurality of insulating films and carbon films alternately laminated on the one side of the substrate, by repeating the forming of the insulating film and the forming of the carbon film multiple times;
removing the carbon films included in the insulating film-carbon film laminate; and
forming electrode films in regions from which the carbon films are removed in the removing of the carbon films to obtain an insulating film-electrode film laminate in which the insulating films and the electrode films are laminated in a plurality of layers.

2. The method of claim 1, wherein the removing of the carbon films is performed by an ashing processing using oxygen plasma.

3. The method of claim 1, wherein the electrode films formed in the forming of the electrode films are tungsten-containing films.

4. The method of claim 1, further comprising:
forming a silicon film before and after the forming of the carbon film is performed.

5. The method of claim 4, wherein the silicon film is oxidized in the removing of the carbon films.

6. The method of claim 1, wherein, in the forming of the carbon film, a film formation temperature of the carbon film is set to range from 500° C. to 900° C.

7. The method of claim 1, wherein the insulating film formed in the forming of the insulating film is a silicon oxide film.

8. The method of claim 1, further comprising:
forming a plurality of hard mask films on the insulating film-carbon film laminate; and
etching the insulating films and the carbon films using the hard mask films as a mask,
wherein the hard mask films include a first inorganic material layer, and a second inorganic material layer made of a material different from a material for the first inorganic material layer.

9. The method of claim 1, further comprising:
forming a word line contact by processing the insulating films and the carbon films in a stepwise form at an end portion of the insulating film-carbon film laminate,
wherein the forming of the word line contact includes:
disposing a mask on the insulating film-carbon film laminate;
etching the insulating film to remove a part of the insulating film;
performing a trimming process to remove a part of the mask and a part of the carbon film; and
repeating alternately the etching of the insulating film and the trimming process.

10. The method of claim 1, further comprising:
forming a trench to penetrate the insulating films and the carbon films of the insulating film-carbon film laminate, and
filling the trench with silicon nitride.

11. A method of manufacturing a semiconductor device, the method comprising:
forming an electrode film on one side of a substrate;
forming a carbon film on the electrode film formed in the forming of the electrode film;
forming an electrode film-carbon film laminate including a plurality of electrode films and carbon films alternately laminated on the one side of the substrate, by repeating the forming of the electrode film and the forming of the carbon film multiple times; and
removing the carbon films included in the electrode film-carbon film laminate.

12. The method of claim 11, wherein the removing of the carbon films is performed by an ashing processing using oxygen plasma.

13. The method of claim 11, further comprising:
forming an insulating film in a region from which the carbon films are removed in the removing of the carbon films.

14. The method of claim 13, wherein the insulating film is a silicon oxide film.

15. The method of claim 11, wherein a region between the electrode films from which the carbon films are removed in the removing of the carbon films forms an air gap.

16. The method of claim 11, wherein, in the forming of the carbon film, a film formation temperature of the carbon film is set to range from 500° C. to 900° C.

17. The method of claim 11, wherein the electrode films formed in the forming of the electrode films are tungsten-containing films.

18. The method of claim 11, further comprising:
forming a plurality of hard mask films on the electrode film-carbon film laminate; and
etching the electrode films and the carbon films using the hard mask films as a mask,
wherein the hard mask films include a first inorganic material layer and a second inorganic material layer made of a material different from a material for the first inorganic material layer.
